(19) United States
(12) Patent Application Publication
(10) Pub. No.: US 2026/0265049 A1
(43) Pub. Date: Sep. 10, 2026

(54) METHOD FOR PRODUCING A MICROSTRUCTURAL ELEMENT AND MICROSTRUCTURAL ELEMENT

(71) Applicant: Fraunhofer-Gesellschaft zur Förderung der angewandten Forschung e.V., Muenchen (DE)

(72) Inventors: Thomas LISEC, Itzehoe (DE); Niels CLAUSEN, Itzehoe (DE); Björn GOJDKA, Itzehoe (DE); Björn JENSEN, Itzehoe (DE); Torben DANKWORT, Itzehoe (DE); Finn KLINGBEIL, Itzehoe (DE)

(73) Assignee: Fraunhofer-Gesellschaft zur Förderung der angewandten Forschung e.V., Muenchen (DE)

(21) Appl. No.: 19/557,166

(22) Filed: Mar. 5, 2026

(30) Foreign Application Priority Data
Mar. 5, 2025 (DE) 102025108367.3

(51) Int. Cl. B81C 1/00; B81B 3/00

(52) U.S. Cl. CPC B81C 1/00666; B81B 3/0072; B81B 2203/0118; B81B 2203/0127; B81B 2203/0307; B81C 2201/0104; B81C 2201/0121; B81C 2201/0132; B81C 2201/0133; B81C 2201/0176

(57) ABSTRACT

A method for producing a microstructural element has: providing a substrate, arranging an indentation structure in a first main surface region thereof, arranging a cover layer on the first main surface region and in the indentation structure, applying a functional layer on the cover layer; planarizing the functional layer to obtain a planar region of the functional layer, which at its opposite, second main surface region extends along the substrate and also into the indentation structure and forms a reinforcement structure; and exposing a movable functional region of the functional layer by removing the substrate below the movable functional region, the reinforcement structure being arranged in an anchoring region of the functional layer on the substrate, and the functional layer without the reinforcement structure having a first thickness d1 and with the reinforcement structure having a second thickness d2, with d2>d1.

### CROSS-REFERENCE TO RELATED APPLICATION

This application claims priority from German Application No. 10 2025 108 367.3, which was filed on Mar. 5, 2025, and is incorporated herein by reference in its entirety.

### TECHNICAL FIELD

The present invention relates to a method for producing a microstructural element and to a corresponding microstructural element. Embodiments relate, in particular, to a method for producing microstructural elements which can be subjected to particularly high mechanical stress, such as, for example, MEMS (microelectromechanical system) structures.

### BACKGROUND OF THE INVENTION

Microelectromechanical systems (MEMS) are currently generally produced by means of semiconductor technology processes on a silicon substrate. An example of this is substrates with a device layer composed of monocrystalline silicon or polysilicon, as are used in large quantities for producing the different MEMS devices. The mechanical properties of the movable microstructures are determined by the thickness of the device layer which, according to the conventional technology, is constant across the entire substrate.

A significant problem of microelectromechanical (MEMS) devices with free-standing, movable microstructures which are based on thin plates or functional layers (device layers) made of silicon or polysilicon is their mechanical strength. Depending on the material of the stressed structures, MEMS devices fail at mechanical stresses of approximately 100 MPa to a few GPa (Pa=Pascal). In the case of inertial sensors, produced by means of surface micromechanical techniques, which are excited in the plane and whose free-standing microstructures are deflected only slightly, high sensitivity with sufficiently good mechanical robustness can be ensured by a corresponding design, for example in the form of mechanical stops or active resetting mechanisms. In other devices, such as, for example, vibration harvesters, micromirrors, microphones, pressure sensors or loudspeakers, the movable, free-standing microstructure, in contrast, due to the application, is to be able to be deflected as far as possible, for example out of the plane. High sensitivity and sufficient mechanical robustness contradict each other here. Thus, the movable microstructure usually has to be designed to be as soft as possible in order to achieve sufficient deflection for a corresponding output signal. At the same time, an MEMS device, depending on the application, has to be able to withstand mechanical shocks or impacts of up to several 1000 g (g=gravitational acceleration) without suffering damage, such as, for example, 2900 g according to the JESd22-B110B standard. In addition to external accelerations due to vibrations, impacts and fall events, fluids (gases or liquids) can exert pressure impacts on the movable microstructure, for example in the case of microphones or pressure sensors. Therefore, there is a great need to increase the mechanical robustness of MEMS devices, however, without substantially increasing the production complexity and, thus, the costs.

With regard to exemplary publications relating to the conventional technology, reference is made to the list of references at the end of the description.

Therefore, the object underlying the present invention is to provide an improved method for producing a microstructural element and an improved microstructural element having improved mechanical properties, such as, for example, higher mechanical strength.

### SUMMARY

According to an embodiment, a method for producing a microstructural element may have the following steps:
providing a substrate,
arranging (at least) one indentation structure in a first main surface region of the substrate, arranging a cover layer (BOX) on the first main surface region and in the indentation structure of the substrate,
applying a functional layer on the cover layer on the first main surface region and in the indentation structure of the substrate;
planarizing the functional layer in order to obtain a planar first main surface region of the functional layer, wherein the functional layer, at its opposite, second main surface region, extends along the substrate and also into the indentation structure of the substrate and forms a reinforcement structure in the indentation structure, and
exposing a movable functional region of the functional layer at least by removing the substrate in regions (vertically) below the movable functional region, wherein the reinforcement structure is arranged at least partly in an anchoring region of the functional layer on the substrate, and wherein the functional layer without the reinforcement structure has a first thickness d1 and the functional layer with the reinforcement structure has a greater, second thickness d2, with d2>d1.

The functional layer can, for example, also have the first thickness d1 in the anchoring region where the reinforcement structure stops. Furthermore, the reinforcement structure can also project partly into the movable functional region. Thus, the functional layer without an (existing) reinforcement structure has a first thickness d1 in the movable functional region and a greater, second thickness d2, with d2>d1, in the anchoring region with an (existing) reinforcement structure (as anchor). In other words, this means that the functional layer has a first thickness d1 in the portion of the movable functional region in which there is no reinforcement structure, and the functional layer has a greater, second thickness d2, with d2>d1, in the portion of the anchoring region in which there is the reinforcement structure.

According to another embodiment, a microstructural element may have:
a substrate provided with a recess, and
a functional layer which spans the recess in the substrate with a movable functional region and has a planar first main surface region, wherein a second, opposite main surface region of the functional layer is coupled to the substrate at an edge region, and wherein the functional layer, at its second main surface region, has at least one reinforcement structure connected directly to the functional layer or formed integrally therewith,
wherein the at least one reinforcement structure is arranged at least partly (partly or completely) in an anchoring region of the functional layer on the substrate, and wherein the functional layer without the reinforcement structure has a first (vertical) thickness d1 and the functional layer with the reinforcement structure has a greater, second thickness d2, with d2>d1.

The inventive procedure for anchoring the functional layer, i.e. the movable functional region of the functional layer, on the substrate allows a more robust and higher-strength configuration of the microstructural element (MEMS component) than conventional MEMS components. In particular, in accordance with the procedure according to the invention, the distribution of the mechanical stress and thus the mechanical strength of movable microstructures, for example of the movable functional region of the functional layer of the microstructural element, which are produced, for example, from a silicon material, can be improved. This is achieved, in particular, by the inventive anchoring of the functional layer and thus of the movable functional region on the associated substrate. The present invention furthermore describes a mass-production-suitable procedure using which the anchoring of the functional layer, which has, for example, a silicon material, on the substrate can be achieved.

In the following description, various exemplary embodiments and application examples of the inventive method for producing a microstructural element and for the inventive microstructural element are illustrated in detail.

### BRIEF DESCRIPTION OF THE DRAWINGS

Embodiments of the present invention are explained in more detail below with reference to the appended drawings and figures, in which:

FIG. 1 shows a schematic flow chart of the inventive production method according to an embodiment;

FIGS. 2a-b show schematic cross-sectional views of exemplary embodiments of the “produced” microstructural element with the inventive anchoring region according to an embodiment;

FIG. 3a shows an exemplary basic flow chart of the inventive production method according to an embodiment;

FIG. 3b shows an exemplary basic flow chart of the inventive production method according to a further embodiment;

FIGS. 4a-b show a comparison of a schematic partial cross-sectional view (a) of an anchoring region of a conventional MEMS component with a schematic partial cross-sectional view (b) of an exemplary embodiment of the anchoring region of the microstructural element produced according to an embodiment;

FIGS. 5a-c show (a) a static simulation of an exemplary FEM (finite element method) model of the microstructural element with the inventive anchoring region, (b) an exemplary representation of the stress distribution (first main stress in N/m² below the anchoring region, and (c) at the concave edge in the material (e.g. polysilicon) of the functional layer in the inventive anchoring region;

FIG. 6 shows a graphical representation of the profile of the maximum mechanical stress in the anchoring of the FEM model in dependence on the curvature radius of the concave edge in the material (e.g. polysilicon) of the functional layer in the anchoring region;

FIG. 7 shows an exemplary basic flow chart of the inventive production method according to a further embodiment;

FIG. 8 shows a graphical representation of the maximum mechanical stress in the cover layer (buried oxide=BOX) below the anchoring region for two different thicknesses of the movable functional region in dependence on the thickness of the anchoring region (for the FEM model of FIGS. 5a-c);

FIG. 9 shows a graphical representation of the maximum mechanical stress at the concave edge in the material (e.g. polysilicon material) of the inventive anchoring region for two plate thicknesses of the movable functional region in dependence on the thickness of the anchoring region;

FIGS. 10a-b show a comparison of a schematic partial cross-sectional view (a) of an anchoring region of a conventional MEMS component with a schematic partial cross-sectional view (b) of an exemplary embodiment of the microstructural element “produced” with the inventive anchoring region according to a further embodiment;

FIGS. 11a-c show (a) a static simulation of an exemplary FEM model of the microstructural element with the inventive anchoring region, (b) an exemplary representation of the stress distribution (first main stress in N/m² below the anchoring region, and (c) at the concave edge in the material (e.g. polysilicon) of the functional layer in the inventive anchoring region (but in contrast to FIG. 5ac with an “undercut” ΔL below the inventive anchoring region and a curvature radius (of 0.5 μm) of the concave edge;

FIG. 12 shows an exemplary basic flow chart of the inventive production method according to a further embodiment;

FIGS. 13a-c show (a) schematic and (b) enlarged representations of the inventive anchoring with a grid-shaped anchoring region as well as (c) the resulting stress distribution below the anchoring region and the stress distribution at a concave edge in the material (e.g. polysilicon) of the functional layer; and

FIGS. 14a-c show an exemplary representation of the surface quality of side walls of an indentation according to a DRIE (Deep Reactive Ion Etching) process; and

FIGS. 15a-c show an exemplary, schematic representation of the structuring of a polysilicon layer by means of a DRIE (Deep Reactive Ion Etching) process and the resulting surface quality of the side walls of the structure obtained (cantilever).

### DETAILED DESCRIPTION OF THE INVENTION

Before embodiments of the present invention are explained in more detail below with reference to the drawings and figures, it is pointed out that identical elements, objects, functional blocks and/or method steps or those of identical function or identical effect are provided with the same designations and/or reference numerals in the various figures so that the description of these elements, objects, functional blocks and/or method steps (with the same designations and/or reference numerals) illustrated various embodiments is interchangeable or mutually applicable.

In the following description, the description of a semiconductor layer means that the semiconductor layer comprises a semiconductor material, i.e. is formed at least partly or also completely from the semiconductor material.

It is to be understood that when an element is referred to as being “connected” or “coupled” to another element, it can be connected or coupled to the other element directly or one or more intermediate elements may be present. In contrast, when an element is referred to as being “connected” or “coupled” to another element “directly”, no intermediate elements are present. Other expressions used to describe the relationship between elements are to be interpreted in the same way (e.g. “between” versus “directly between”, “adjacent” versus “directly adjacent”, etc.).

To simplify the description of the different embodiments, at least some of the figures comprise a Cartesian coordinate system x, y, z, wherein the directions x, y, z are arranged orthogonally to one another. In the embodiments, the x-y plane corresponds to the (upper) main surface region of a carrier or substrate (=reference plane=x-y plane), wherein the direction vertical thereto upwards with respect to the reference plane (x-y plane) corresponds to the “+z” direction, and wherein the direction vertically downwards with respect to the reference plane (x-y plane) corresponds to the “−z” direction. In the following description, the expression “lateral” means a direction parallel to the x and/or y direction, i.e. parallel to the x-y plane, wherein the expression “vertical” indicates a direction parallel to the +/−z direction.

In the following description, a thickness or height of an element usually indicates a vertical dimension of this element, whereas a width or length of an element usually indicates a lateral dimension of this element. In the figures, the various elements are not necessarily drawn to scale. Thus, the lateral and vertical dimensions of the described elements, e.g. the thicknesses and widths of the individual semiconductor layers, insulation layers, of the semiconductor substrate, etc., cannot be drawn to scale.

In the context of the present description, terms and/or text passages put into parentheses are to be understood to be further alternative designations or exemplary explanations, configurations, additions or alternatives (to the associated term or the associated text passage).

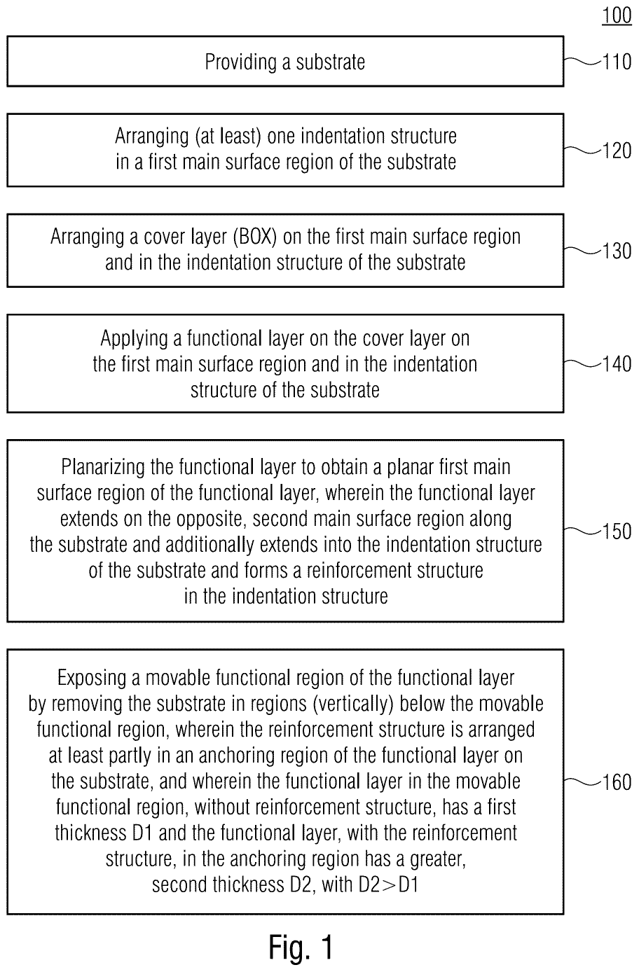

FIG. 1 shows a schematic flow chart of the inventive production method 100 of a microstructural (or micropatterned) element 10 according to an embodiment.

In the method 100 for producing a microstructural element 10, a substrate is at first provided in step 110. In step 120, (at least) one indentation structure is arranged in a first main surface region of the substrate. In step 130, a cover layer, e.g. in the form of a buried oxide (BOX), is arranged on the first main surface region and in the indentation structure of the substrate. In step 140, a functional layer is applied on the cover layer on the first main surface region and in the indentation structure of the substrate. In step 150, the functional layer is planarized in order to obtain a planar first main surface region of the functional layer, wherein the functional layer extends at its opposite, second main surface region along the substrate and also into the indentation structure of the substrate and forms a reinforcement structure in the indentation structure. In step 160, a movable functional region of the functional layer is exposed at least by removing the substrate in regions (vertically) below the movable functional region, i.e. the substrate is removed in regions (vertically) below a movable functional region and the movable functional region of the functional layer is exposed.

In step 160, according to an embodiment, the movable functional region of the functional layer can be exposed by removing the substrate in regions, e.g. vertically, below the movable functional region. This is the case, for example, if the movable functional region is formed tp be a circumferentially fixed, deflectable membrane. According to a further embodiment, in the production step 160, the functional layer can also be structured in regions in the plane, e.g. by means of a front-side process, in order to obtain the movable functional region, e.g. as a deflectable beam element. The functional layer can thus be removed in regions for exposing the movable functional region (e.g. as a deflectable beam element).

The reinforcement structure is arranged at least partly, i.e. partly or completely, in an anchoring region of the functional layer on the substrate, wherein the functional layer without the reinforcement structure has a first thickness d1 and the functional layer with the reinforcement structure has a greater, second thickness d2, with d2>d1.

The functional layer can, for example, also have the first thickness d1 in the anchoring region where the reinforcement structure stops. Furthermore, the reinforcement structure can also project partly into the movable functional region. Thus, the functional layer without an (existing) reinforcement structure in the movable functional region has a first thickness d1 and a greater, second thickness d2, with d2>d1, in the anchoring region with an (existing) reinforcement structure (as anchor). In other words, this means that the functional layer has a first thickness d1 in the portion of the movable functional region where there is no reinforcement structure, and the functional layer has a greater, second thickness d2, with d2>d1, in the portion of the anchoring region where there is the reinforcement structure.

According to an embodiment, the indentation structure can be arranged in the substrate with such a depth and the functional layer can be applied on the substrate with such a thickness that, after planarization (in step 150), the reinforcement structure of the functional layer has a greater, second thickness d2, with d2≥2*d1. Thus, the indentation structure can be arranged in the substrate with such a depth and the functional layer can be applied on the substrate with such a thickness that, after planarization, the first thickness d1 of the functional layer is between 2 and 125 μm or between 3 and 80 μm and the second thickness d2 of the reinforcement structure, with d2≥2*d1, is between 4 and 250 μm or between 6 and 160 μm.

In step 140 of applying a functional layer, a material layer can be applied, which for example comprises or consists of polysilicon, monocrystalline silicon or also other materials, such as for example metals or dielectrics. The possible thicknesses of the applied material of the functional layer are defined by the available deposition or application processes.

The functional layer can, for example, also be applied at least partly (or completely) as a stack of two or more layers made of the same material or of different materials. Thus, an additional layer for the (resulting) functional layer or the functional layer stack can be applied, for example after planarization (step 150 of the production method 100). Furthermore, individual or all the layers of the functional layer can be planarized or the functional layer stack can finally be planarized in step 150. By configuring the functional layer as a layer stack, the mechanical properties thereof can be set or increased in an extended range. Thus, a layer stack offers additional degrees of freedom for setting the mechanical properties of the movable functional region of the functional layer.

In the etching process of step 160, in which the movable functional region of the functional layer is exposed, the cover layer can, for example, serve as an etch stop layer for the etching process. According to an embodiment, in step 160 of exposing a movable functional region of the functional layer, the cover layer can also be removed, e.g. vertically, below the movable functional region, at least in regions, i.e. in regions or completely. Alternatively, the cover layer can also remain on the movable functional region of the functional layer and (if required), for example, assume a protective function for the movable functional region, e.g. against disturbing environmental influences.

With regard to the present description of embodiments of the inventive production method, it is pointed out that the movable functional region of the microstructural element can have substantially any configuration and shape in the plane (or laterally). Thus, the functional layer can be structured before or after exposing in step 160. Depending on the material, a suitable process can be used for structuring the functional layer. If, for example, polysilicon is used for the functional layer, the structuring can take place, for example, by means of DRIE. Thus, for example, after applying a lithographic mask (photolithography), an etching process can be carried out from the upper side (front side) of the functional layer, e.g. by means of DRIE.

According to an embodiment, the reinforcement structure can be arranged as a one-piece or integral, e.g. beam-shaped, reinforcement element on the second main surface region of the functional layer.

According to an embodiment, the reinforcement structure with a plurality of reinforcement elements can be arranged on the second main surface region of the functional layer, i.e. the reinforcement structure can have a plurality of reinforcement elements on the second main surface region of the functional layer. Thus, for example, the reinforcement elements can be arranged adjacently and/or connected to one another, e.g. in a grid-shaped manner, wherein the reinforcement elements can be arranged to be, e.g. elongated, lamellar, rib-shaped, honeycomb-shaped, grid-shaped, elliptical, circular, or wavelike or arcuate, etc., on the second main surface region of the functional layer. The configuration of the reinforcement elements of the reinforcement structure can depend, for example, on the shape of the movable functional region, on the anchoring of the movable functional region on the substrate and/or on the desired local rigidity of the functional layer or of the movable functional region of the functional layer.

In the case of reinforcement structures with a plurality of reinforcement elements, reinforcement elements, e.g. in the form of a grid, are to be provided along the transition edges of regions with the greater thickness d2, in movable functional regions with the smaller thickness d1.

According to an embodiment, the indentation elements of the indentation structure can be arranged with a maximum width (indentation width) in the first main surface region of the substrate, wherein the functional layer is applied with a layer thickness which corresponds to at least half the maximum width of the indentation elements. Thus, the maximum width of the individual indentation elements can be less than half the thickness of the functional layer, wherein the indentation elements, however, may also have different widths to one another while taking this boundary condition into consideration.

According to an embodiment, the indentation structure can be arranged at such a position in the substrate that the (then obtained) reinforcement structure is arranged on the second main surface region of the functional layer at the clamping region (anchoring region) of the functional layer or extends from the clamping region of the functional layer into the movable functional region of the functional layer.

According to a further embodiment, a further indentation structure can optionally be arranged at such a position in the substrate that the (then obtained) reinforcement structure is arranged completely on the exposed second main surface region of the movable functional region of the functional element. Thus, the reinforcement structure can be provided in an island-like manner on the movable functional region of the functional element in order to obtain a local modification of the rigidity or reinforcement of the movable functional region.

Some examples of possible configurations of the movable functional region which can be obtained, for example, with the inventive production method 100 are illustrated below. Thus, in particular, the production step 160 can be carried out to expose any of the configurations (embodiments) of the movable functional region of the functional layer illustrated below by structuring the functional layer in the plane and removing the substrate in regions, e.g. vertically, below the movable functional region.

Thus, the movable functional region can be clamped on one side as a beam element (cantilever, bending beam or deflectable plate), wherein the reinforcement structure can be provided, for example, on the clamping region (anchoring region) with the substrate and an (optional) further reinforcement structure may also be provided in the exposed beam region. In a configuration as a bending beam (or bending plate) with a mass element (inert mass), an (additional) reinforcement structure can also be provided, for example, on the anchoring region of the mass element with the beam element, wherein, in the case several reinforcement structures, these may have the same thickness or, based on the different position, may also have different thicknesses. In order to obtain the movable functional region as a deflectable beam element, in the production step 160, the functional layer can also be structured in regions in the plane, e.g. by means of a front-side process, i.e. be removed in places for exposing the movable functional region (as a deflectable beam element).

According to a further embodiment, the movable functional region can also be formed, for example, as a circumferentially fixed, deflectable membrane which optionally also has a mass element in the movable functional region. Thus, for example, the circumferential anchoring region can have a corresponding, circumferential reinforcement structure around the movable functional region. According to an embodiment, the (circumferential) reinforcement structure can extend, for example, partly into the movable functional region. In order to obtain or expose the movable functional region as a circumferentially fixed, deflectable membrane, in the production step 160, for example, no front-side etching process on the functional layer is required.

Furthermore, in the case of a circumferentially fixed, deflectable membrane as a movable functional region, the reinforcement structure can also be arranged only in regions or in portions (e.g. uniformly spaced apart or symmetrically) on the circumferential anchoring region of the functional layer. If there are portions or regions along the clamping of a circumferentially fixed membrane where the occurrence of high mechanical stress is excluded, no reinforcement structure needs to be provided there. However, the reinforcement elements are to be arranged sufficiently densely so that they “support” one another, i.e. high or excessive mechanical stress cannot occur in the regions therebetween.

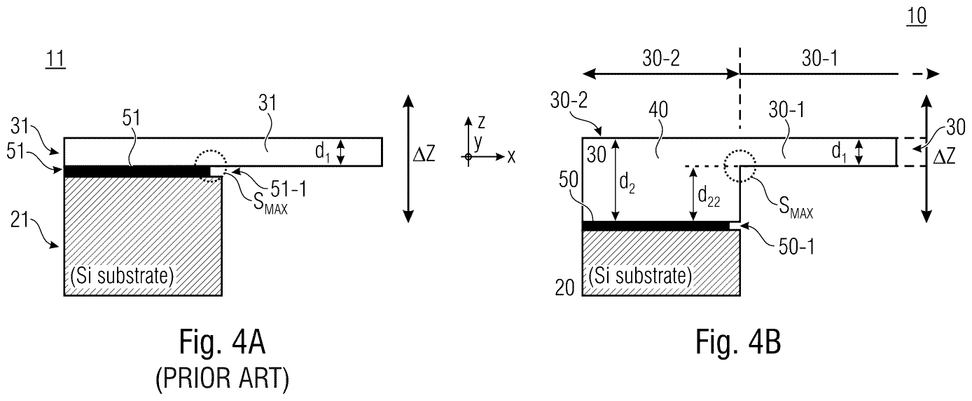

According to a further exemplary embodiment, the movable functional region can also be formed as a deflectable membrane fixed in portions which optionally also has a mass element in the movable functional region. The clamping region can thus be divided into several portions along the circumference of the membrane. These portions can be arranged, for example, to be uniformly (symmetrically) distributed around the movable functional region. As has already been indicated above, one or more reinforcement structures can be arranged on the clamping regions (anchoring regions) of the functional layer and optionally also on the movable functional region. For example, several reinforcement structures can be arranged in a portion if no excessively high mechanical stress occurs at a critical location, e.g. in the cover layer (BOX) 50, in the regions located therebetween (according to FIG. 4a).

The above-described different reinforcement structures on the anchoring region or the anchoring regions and optionally on the movable functional region can be dimensioned identically or can also have different thicknesses and different lateral dimensions.

In the following, in the method 100, arranging a rigid element, such as e.g. a mass element or inertial mass element, on the movable functional region of the functional layer is illustrated by way of example. Thus, in step 120 of arranging, a further indentation structure can be provided in the first main surface region of the substrate. In step 130, the cover layer is arranged in the further indentation structure of the substrate. Furthermore, in step 140, the functional layer is also applied on the cover layer in the further indentation structure of the substrate and planarized subsequently (step 150). In step 160 of exposing the movable functional region of the functional layer, a rigid element, such as a mass element (inertial mass element), can also be formed in the rear side opening of the substrate on the movable functional region or within the movable functional region of the functional layer. In order to obtain the movable functional region as a deflectable beam element, in the production step 160, the functional layer can also be structured in regions in the plane, e.g. by means of a front-side process, i.e. be removed in places for exposing the movable functional region (as a deflectable beam element).

The mass element has, for example, an exposed material region of the substrate. The further reinforcement structure is arranged at least partly in the (further) anchoring region of the mass element on the functional layer. The mass element is thus supported to be deflectable on the movable functional region of the functional layer. The further reinforcement structure of the functional layer has, for example, the second thickness d2, with d2>d1 or d2≥2*d1, wherein the further reinforcement structure can also have a further thickness d3, with d3>d1 or d3≥2*d1, wherein d3≠d2. Thus, the reinforcement structure (the anchor) of the movable functional region on the substrate and the further reinforcement structure (anchor) on the mass element can have identical or also different thicknesses, but at least a thickness of >d1.

According to an embodiment, the further indentation structure can be arranged in the substrate with such a depth and the functional layer can be applied on the substrate with such a thickness that, after planarization (in step 150), the further reinforcement structure of the functional layer has a greater, third thickness d3, with d3≥2*d1, and the first thickness d1 of the functional layer is between 2 and 125 μm or between 3 and 80 μm and the third thickness d3 of the further reinforcement structure, with d3≥2*d1, is between 4 and 250 μm or between 6 and 160 μm.

According to an embodiment, the movable microstructure (the movable functional region) of the functional layer can also be anchored at several positions on the substrate so that the mass element is suspended on several flexible plates or beams. Furthermore, the movable functional region of the functional layer can have any shape in the lateral plane and can be anchored at several locations or also circumferentially.

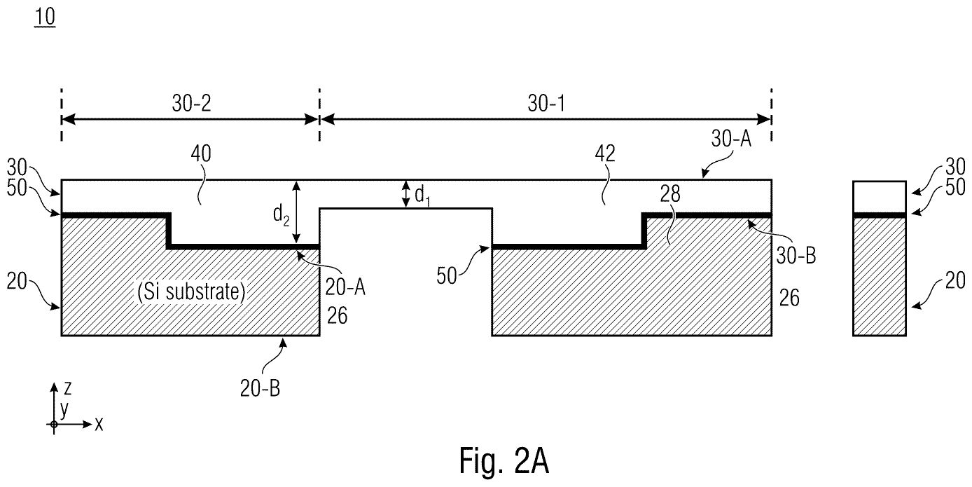

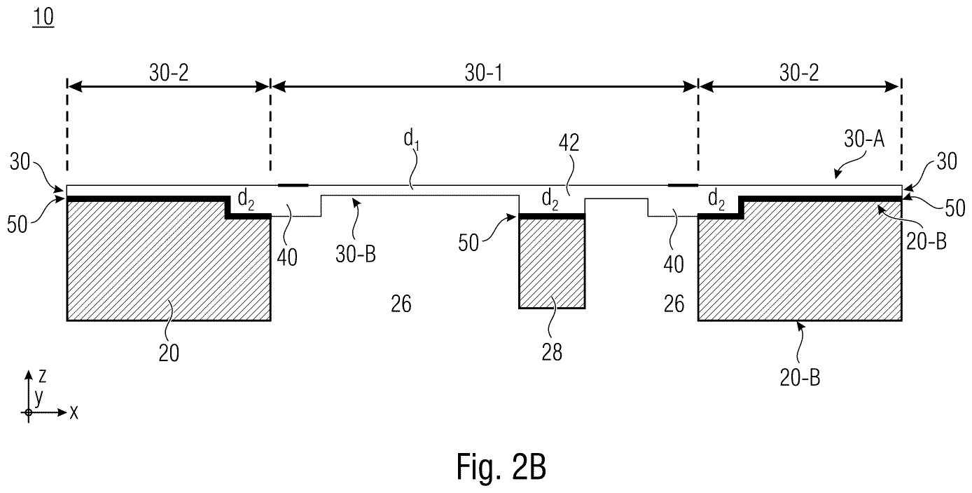

According to an embodiment, in step 160 of exposing the movable functional region, the functional layer can also be removed in regions (e.g. by means of a front-side etching process) in order to obtain the movable, deflectable functional region as a deflectable arm or a deflectable plate, e.g. for a mass element. With reference to the cross-sectional view of FIG. 2a, a continuous recess (rear side opening or through opening) 26 through the substrate 20, the cover layer 50 and the functional layer 30 is shown on the right in the plane of the drawing. In step 160, the rear side opening through the substrate 20 can end e.g. in the cover layer 50 (if this is effective as an etch stop layer), while in a front-side process the functional layer 30 and e.g. also the cover layer 50 are removed in regions (above the rear side opening). The cover layer 50 can, however, be removed (in regions) in the recess 26 in the substrate 20 either with a rear side process or a front-side process. Thus, the cover layer (the oxide) 50 can be removed in a planar manner in the regions where the substrate 20 was previously removed. This can take place by (anisotropic) RIE (from the substrate rear side) or by the same (isotropic) etching process with which the movable functional region, e.g. an inertial sensor, of the functional layer 30 is etched free from the front side.

According to a further embodiment, the production method 100 can additionally have a step 125 of performing a rounding process of corner and/or edge regions at the first main surface region of the substrate provided with the at least one indentation in order to obtain curvature or rounding radii between 0.5 μm and 9 μm or between 1 and 7 μm or between 1.5 μm and 5 μm at the (rounded) corner and/or edge regions. At the same time, the rounding process can lead in a smoothing of the first main surface region of the substrate provided with the at least one indentation, including the surfaces of the indentation.

By this rounding of edges and corners at the first main surface region of the substrate provided with the at least one indentation, correspondingly rounded (curved) corners and edges can then be obtained at the second main surface region of the functional layer and thus at the (then obtained) reinforcement structure. By these roundings (curvings) of the functional layer and, in particular, of the reinforcement structure, maximum mechanical stress in the functional layer (then provided with such roundings) can be reduced significantly (when compared to a non-rounded state). In the same way, smoothing of the first main surface region of the substrate results in the surfaces of the second main surface region of the functional layer to be smoother. This can increase the breaking strength of the movable microstructure considerably.

According to an embodiment, the rounding process can e.g. be performed in step 125 of corner and/or edge regions at the first main surface region of the substrate provided with the at least one indentation, with a dry etching process, oxidation process or tempering process in hydrogen.

According to an embodiment, step 160 of exposing the movable functional region of the functional layer can be performed starting from the second main surface region of the substrate by means of an anisotropic etching process in order to obtain a recess or a rear side opening (through opening) 26 through the substrate 20. Such an anisotropic etching process can, for example, comprise a so-called Bosch process or a DRIE (Deep Reactive Ion Etching) process in order to obtain the recess in the substrate, wherein the cover layer can, for example, serve as an etch stop layer for the etching process.

According to an embodiment, the substrate can, for example, comprise a silicon material, wherein the functional layer can comprise a poly-Si material and the cover layer can comprise an oxide material, for example silicon oxide.

According to an embodiment, the indentation structure can be arranged in the substrate with such a depth and the functional layer can be applied on the substrate with such a thickness that, after the planarization step 150, the functional layer has the first thickness of at least 2 μm or between 2 μm and 125 μm.

FIGS. 2a-b show schematic cross-sectional views of exemplary embodiments of the (produced) microstructural element 10 with a reinforcement structure 40 in the anchoring region 30-2 of the functional layer 30 according to an embodiment.

As shown exemplarily in FIG. 2a, the movable functional region 30-1 of the functional layer 30 can be formed as a beam element (cantilever, bending beam or deflectable plate) and clamped on one side.

As shown exemplarily in FIG. 2B, the movable functional region 30-1 of the functional layer 30 can, for example, also be formed as a deflectable membrane which is circumferentially fixed or is fixed in portions (along the circumference).

According to the embodiment of FIGS. 2a-b, the microstructural element 10 comprises a substrate 20 provided with a recess 26 and a functional layer 30. The functional layer 30 spans the recess 26 in the substrate 20 with a movable functional region 30-1 and has a planar (level) first main surface region 30-A. The second, opposite main surface region 30-B of the functional layer 30 is coupled to the substrate 20 or anchored to the substrate 20 at an edge region (anchoring region) 30-2. The functional layer 30, at its second main surface region 30-B, has at least one reinforcement structure 40 directly connected to the functional layer or formed integrally therewith. The at least one reinforcement structure 40 is arranged at least partly, i.e. partly or completely, in an anchoring region 30-2 of the functional layer 30 (for anchoring the functional layer 30 to the substrate 20), wherein the functional layer 30 without the reinforcement structure has a first (vertical) thickness d1 in the movable functional region 30-1 and the functional layer 30 with the reinforcement structure 40 has a greater, second thickness d2, with d2>d1. According to an embodiment, the reinforcement structure 40 of the functional layer 30 can have the greater, second thickness d2, with d2≥2*d1, in the anchoring region 30-2. In the following, the reinforcement structure 40 of the functional layer 30 in the anchoring region 30-2 is also referred to as an “anchor”, for example.

The functional layer 30 can, for example, also have the first thickness d1 in the anchoring region 30-2 where the reinforcement structure 40 stops. Furthermore, the reinforcement structure 40 can also project partly into the movable functional region 30-1. Thus, the functional layer 20 without an (existing) reinforcement structure has a first thickness d1 in the movable functional region 30-1 and a greater, second thickness d2, with d2>d1, in the anchoring region 30-2 with an (existing) reinforcement structure (as anchor) 40. In other words, this means that the functional layer 20 has a first thickness d1 in the portion of the movable functional region 30-1 where there is no reinforcement structure 40, and the functional layer 20 has a greater, second thickness d2, with d2>d1, in the portion of the anchoring region 30-2 where there is the reinforcement structure 40.

According to an embodiment, the first thickness d1 of the functional layer 30 can be between 2 and 125 μm or between 3 and 80 μm and the second thickness d2 of the reinforcement structure, with d2≥2*d1, can be between 4 and 250 μm or between 6 and 160 μm.

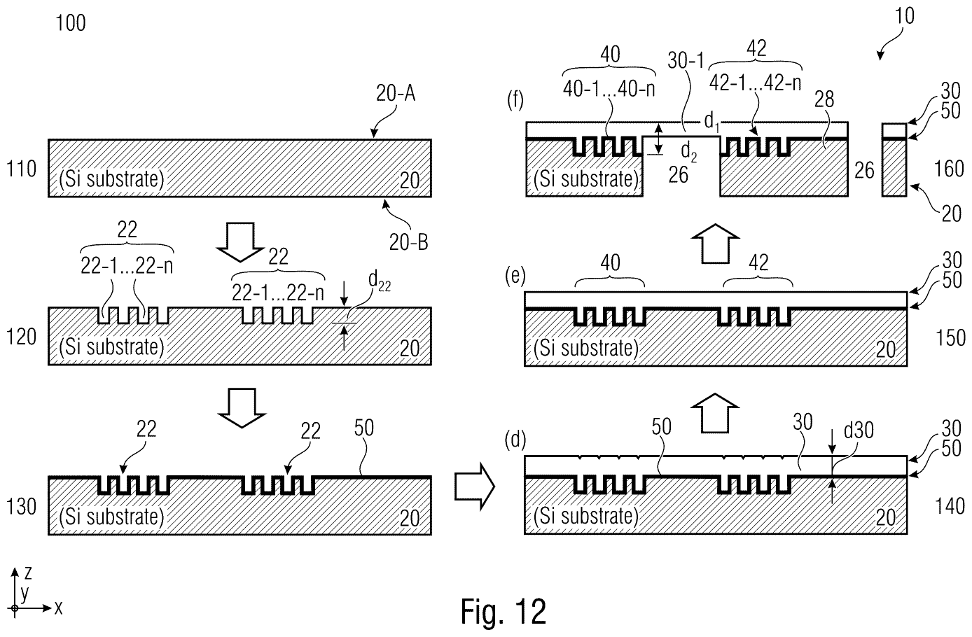

According to an embodiment, the reinforcement structure 40 can be formed as a one-piece (integral) reinforcement element on the second main surface region 30-B of the functional layer 30. According to a further embodiment (see also FIG. 12), the reinforcement structure 40 can have a plurality of reinforcement elements 40-1, . . . , 40-n (with n=2, 3, 4, . . . ) on the second main surface region of the functional layer.

According to an embodiment, the reinforcement structure 40 is arranged in the anchoring region 30-2 on the second main surface region 30-B of the functional layer 30 and extends from the anchoring region (clamping region) 30-2 of the functional layer 30 into the movable functional region 30-1 of the functional layer 30.

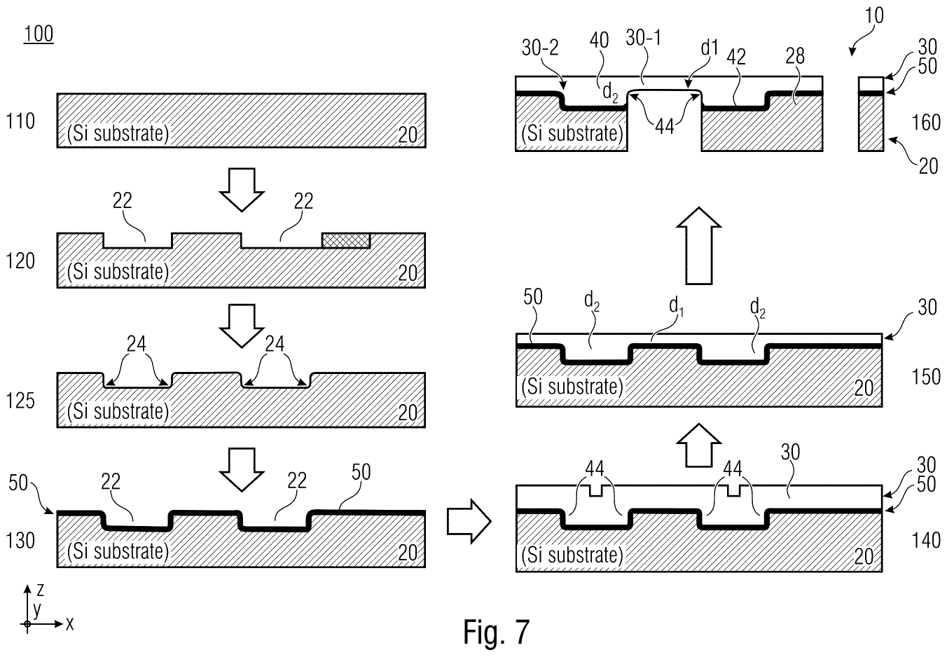

According to an embodiment (see also FIG. 7), edge and/or corner regions are rounded at the movable region 30-1 of the functional layer 30 and have, for example, curvature radii between 0.5 μm and 9 μm or between 1 μm and 7 μm or between 1.5 μm and 5 μm.

According to a further embodiment, the substrate 20 comprises a silicon material, wherein the functional layer 30 comprises a poly-Si material and the cover layer 50 comprises an oxide material, for example thermal oxide. According to an embodiment, the functional layer has a first thickness d1 of at least 2 μm or between 2 and 125 μm.

According to a further embodiment, the microstructural element 10 is formed as a deflectable device.

As shown in FIG. 2a in the configuration of the movable functional element 30-1 as a bending beam (or bending plate) with an (optional) mass element (inert mass) 28 and in FIG. 2b in the configuration of the movable functional element 30-1 as a deflectable membrane where an (optional) mass element 28 can be arranged, an (additional) reinforcement structure 42 can also be provided, for example, on the anchoring region of the mass element 28 with the movable functional element 30-1.

The (optional) mass element 28 can thus be supported to be deflectable on the movable functional region 30-1 of the functional layer 30 provided with the further reinforcement structure 42. The further reinforcement structure 42 of the functional layer 30 has, for example, the second thickness d2, with d2>d1 or d2≥2*d1, wherein the further reinforcement structure can also have a further thickness d3, with d3>d1 or d3≥2*d1, wherein d3≠d2. Thus, the reinforcement structure (the anchor) 40 of the movable functional region 30-1 on the substrate 20 and the further reinforcement structure (anchor) 42, e.g. on the mass element 28, can have identical or also different thicknesses, but at least a thickness of >d1.

The further reinforcement structure 42 can also be arranged without (the optional) mass element 28, e.g. in an island-like manner, on the movable functional region 30-1 of the functional element 30 of FIGS. 2a-b in order to obtain a local modification of the rigidity of the movable functional region 30-1.

The further reinforcement structure (anchor region) 42 for the mass element is an optional configuration of the movable functional region 30-1 of the functional element 30 in the embodiments of the inventive production method 100 illustrated in the context of the present description.

In the following, some essential aspects of the production method 100 of a microstructural element 10 illustrated with reference to FIG. 1 and of the microstructural element 10 described with reference to FIGS. 2a-b are illustrated once again in summary.

When deflecting the movable functional region 30-1 of the functional layer (device layer) 30 perpendicular (vertically) to the lateral substrate plane, maximum mechanical stress occurs at a position of the microstructural element 10 where the movable functional region 30-1 (the movable microstructure) of the functional layer 30 merges into the rigid part of the component (of the microstructural element) 10. In the inventive anchoring, as described in FIGS. 1 and 2a-b, the region of the maximum stress in the anchoring region remains completely in the material of the functional layer 30, i.e. in the transition region of the functional layer 30 without reinforcement structure to the functional element 30 with the reinforcement structure 40. With a sufficiently large thickness d2 (anchor thickness) of the reinforcement structure 40, the material, e.g. the oxide material, of the cover layer 50 located under the anchoring region 30-2 is exposed to only low mechanical stress so that the strength of the inventive anchoring is determined by the mechanical properties of the material, e.g. the polysilicon material, of the functional layer 30 in the anchoring region 30-2.

The procedure according to the invention for anchoring the functional layer 30, i.e. the movable functional region 30-1 of the functional layer 30, on the substrate 20 allows a robust and high-strength configuration of the microstructural element (MEMS device) 10. In particular, in accordance with the procedure according to the invention, such a distribution of the mechanical stress in the device can be achieved that materials with lower mechanical strength, for example the cover layer consisting of silicon oxide, are not exposed to the maximum mechanical stress which can occur in the region of the anchoring, and thus the mechanical strength of movable microstructures, e.g. the movable functional region 30-1 of the functional layer 30 of the microstructural element 10, which are produced, for example, from a silicon material, can be increased. This is achieved, in particular, by the inventive anchoring of the functional layer 30 with its movable functional region 30-1 on the associated substrate 20. The present invention also describes a mass-production-suitable procedure using which robust anchoring of the functional layer 30, which has, for example, a silicon material, on the substrate can be achieved by locally increasing the thickness and thus the mechanical property of the functional layer 30 at the anchoring region.

By the optional arrangement of a further reinforcement structure 42 (e.g. without the optional mass element 28) on the exposed second main surface region 30-B of the movable functional region 30-1 of the functional element 30, a specific local modification of the rigidity of the movable functional region 30-1 of the microstructural element 10, e.g. a movable microstructure for an MEMS, can be obtained since the thickness of the functional layer 30 vertically to the substrate plane can be varied in regions (locally) and set in a specific manner. By the additional local stiffening, for example, an undesired deformation of the movable functional region 30-1 of the functional layer 30, e.g. due to acceleration forces or external effects during operation of the microstructural element 10, can be prevented or at least reduced significantly.

FIGS. 2a-b show several exemplary configurations of the reinforcement structures 40, 42 at different reinforcement positions for the functional layer 30, wherein in the inventive production method 100, at a position to be reinforced, an individual one of the reinforcement structures 40, 42, or at several positions to be reinforced, any combination of several reinforcement structures 40, 42 can be arranged on the second main surface region 30-B of the functional layer 30 in order to obtain the desired local stiffening(s) of the movable functional region 30-1 of the functional layer 30.

In the inventive production method 100, for example, silicon and/or polysilicon materials can be used for the functional layer 30 and the reinforcement structure 40, 42 arranged thereon, thereby obtaining high mechanical strength and good thermal conductivity of the correspondingly formed functional layer.

The inventive production method 100 thus allows selected regions of the functional layer of the microstructural element to be stiffened locally in a specific manner, while other regions of the functional layer remain flexible and correspondingly deflectable. Thus, the microstructural element provided with the reinforcement structure 40 can, for example, be used continuously as a sensor, actuator, vibration harvester, inertial sensor, loudspeaker, micromirror, microphone, pressure sensor, etc., but with increased mechanical robustness. The procedure according to the invention is applicable not only to the above-mentioned devices but substantially to any MEMS devices. According to an embodiment, the microstructural element 10 can, for example, also be formed as a sensor element in order to detect a deflection of the movable functional region 30-1 of the functional layer 30 by means of a capacitive, piezoelectric or piezoresistive readout technique.

The inventive production method 100 can be implemented without (substantially) any increased production complexity when compared to a conventional procedure and has, in particular, exact reproducibility of the reinforcement structure(s) 40, 42 arranged on the movable functional region 30.

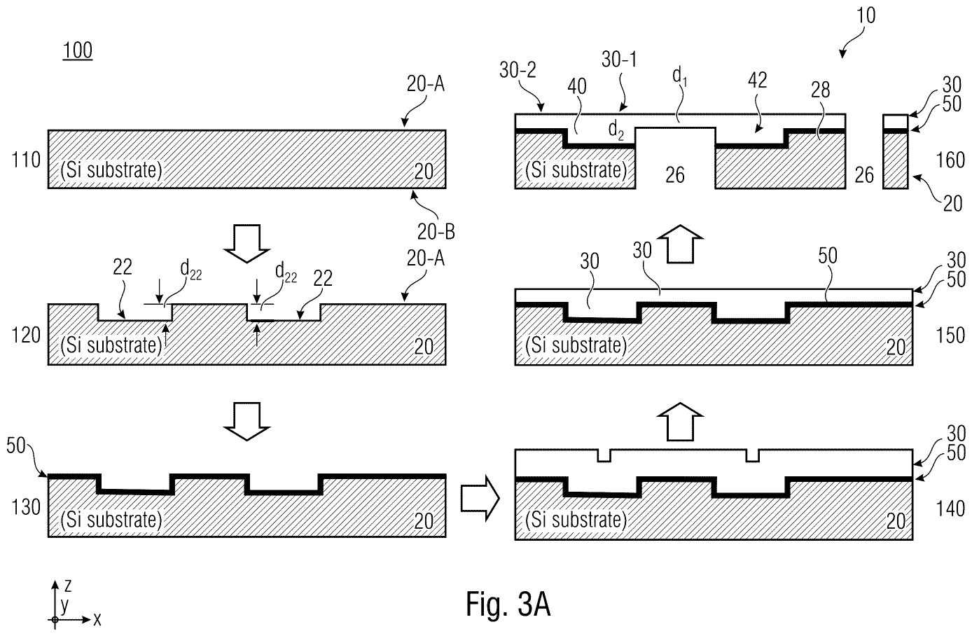

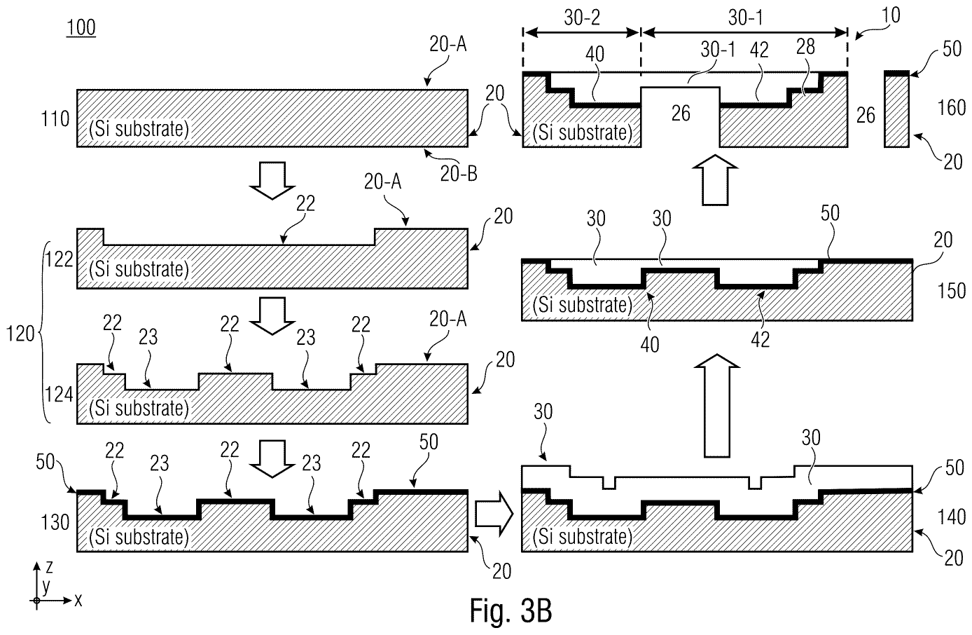

In the following, an exemplary basic flow chart (flow diagram) of the inventive production method 100 according to an embodiment is illustrated with reference to FIG. 3a. FIG. 3a describes, by way of example, an inventive procedure of the method 100 for producing a microstructural element 10, wherein the functional layer 30, which has, for example, a semiconductor material such as silicon or polysilicon, has a reinforcement structure (an anchor) 40 of increased thickness in the anchoring region 30-2 to the substrate 20. Furthermore, the thickness of the movable functional region 30-1 of the functional layer 30 can be varied locally by means of a further reinforcement structure 42. The embodiment described is applicable to producing any MEMS devices or MEMS microstructures.

As illustrated in FIG. 3a, a substrate 20 is provided in step 110. The starting material can thus be a semiconductor substrate, such as e.g. a silicon substrate or an SOI (silicon-on-insulator) substrate.

In step 120, (at least) one indentation structure 22 with a depth d₂₂ is arranged in the first main surface region 20-A of the substrate 20. In step 120, the indentation structure 22 (with one or more indentations 22) is produced, for example, by dry etching or wet etching at the positions where the reinforcement structure 40, 42 (which can optionally also have a plurality of reinforcement elements 40-1, . . . , 40-n-see e.g. also FIG. 12) can then be produced in the subsequent steps. In step 130, the cover layer 50 is arranged (applied) on the first main surface region 20-A and in the indentation structure 22 of the substrate 20. The cover layer 50 covers (independently of the cover material used) not only the surface 20-A of the substrate 20, but also the bottom and side walls of the indentations 22. The cover layer 50 comprises, for example, an insulation material, such as e.g. an oxide material (buried oxide=BOX). In the case of an oxide material, the oxide layer 50 can be obtained, for example, by a thermal oxidation process of the silicon substrate, e.g. as a silicon oxide layer.

In the subsequent step 140, the functional layer (device layer) 30 is applied on the cover layer 50 on the first main surface region 20-A and in the indentation structure 22 of the substrate 20. The functional layer 30 can, for example, be deposited as a polysilicon material (poly-Si material) on the cover layer 50. The material thickness of the functional layer 30 is to be formed sufficiently large to not only fill the indentation(s) 22, but also to obtain the thickness of the resulting functional layer 30 with the movable functional region 30-1 in the region of the indentation(s) 22.

The functional layer 30 can, for example, be applied by depositing, on the front side 20-A of the substrate 20 covered with the cover layer 50, by means of a CVD (chemical vapor deposition) process, the material, e.g. polysilicon, of the functional layer 30, which then later also forms the movable functional region 30-1 of the functional layer 30. The thickness of the functional layer 30 can, for example, be in a range from 2 μm to about 125 μm.

Alternatively, the functional layer 30 can also comprise or consist of a monocrystalline silicon material, corresponding to an SOI (silicon-on-insulator) structure. SOI substrates 20 are produced, for example, by bonding and thinning silicon substrates and are thus also available at thicker functional layers 30.

The thickness of the cover layer (buried oxide) 50 can, in the case of silicon oxide, typically be in a range between 0.5 μm and 2 μm, independently of the type of functional layer 30.

In step 150, the functional layer 30 is planarized in order to obtain the planar (level) first main surface region 30-A of the functional layer 30. The functional layer 30, at its opposite, second main surface region 30-B, extends along the substrate 20 and also into the indentation structure(s) 22 of the substrate 20 in order to form the (respective) reinforcement structure 40, 42 in the (respective) indentation structure 22. In step 150, the material of the functional layer 30 is planarized, wherein, under certain circumstances, a considerable material thickness (polysilicon thickness) is to be removed. In addition to a CMP (chemical mechanical polishing) process, further grinding and polishing processes may be required or used. The resulting functional layer 30 thus has regions with a smaller first thickness d1, which transition “seamlessly” into regions (reinforcement regions) 40, 42 with a greater second thickness d2 or also third thickness d3 in the indentations, i.e. the thickness of the functional layer 30 varies locally over the area (surface) of the substrate 20.

In step 160 of exposing the movable functional region 30-1 of the functional layer 30, the substrate 20 is then removed (in regions) below the movable functional region 30-1, wherein the reinforcement structure 40 is then arranged at least partly, i.e. partly or also completely, in the anchoring region 30-2 of the functional layer 30 on the substrate 20, and wherein the functional layer 30 has a first thickness d1 in the movable functional region 30-1 without the reinforcement structure and the functional layer 30 with the reinforcement structure 40 has a greater, second thickness d2, with d2>d1.

As shown exemplarily in FIG. 3a in step 160, the microstructural element 10 of FIG. 2a can be obtained, wherein the movable functional region 30-1 of the functional layer 30 is formed as a beam element (cantilever, bending beam or deflectable plate) clamped on one side. For this purpose, in the production step 160, the functional layer 30 is also removed in regions or structured in the plane in order to expose the movable functional region 30-1 as a deflectable beam element.

According to a further embodiment of the present invention, in step 160 of FIG. 3a, for example, the microstructural element 10 of FIG. 2b can also be obtained, in which the movable functional region 30-1 of the functional layer 30 is formed as a deflectable membrane which is fixed circumferentially or fixed in portions along the circumference.

In the etching process of the substrate (starting from the substrate rear side 20-B) of step 160, the cover layer 50 can, for example, serve as an etch stop layer for the etching process in order to obtain the desired implementation and topography of the second main surface region 30-B of the functional layer. According to an embodiment, in step 160, the cover layer 50 can also be removed at the movable functional region 30-1 at least in regions, i.e. in regions or completely. Alternatively, the cover layer 50 can also remain on the movable functional region 30-1 of the functional layer 30 and (if required), for example, assume a protective function for the movable functional region 30-1, e.g. against disturbing environmental influences.

According to the production method 100 illustrated in FIG. 3a, an individual region 40 or also a plurality of regions 40, 42 with increased thickness (and thus increased mechanical rigidity) can be produced in the functional layer 30. For this purpose, in the step of arranging 120 the indentation structure 22 in the first main surface region of the substrate 20, a corresponding number of indentations 22 is provided at such a position in the substrate where the reinforcement structure(s) 40, 42 is/are to be arranged on the functional layer 30 subsequently in the further process steps. The regions of the further indentations 22 can occur at different positions on the first main surface region 20-A of the substrate 20 or also within already existing indentations 22 in order to obtain, for example, reinforcement structures 40, 42 of different thickness in the subsequent production steps.

In the production method 100, described with reference to FIG. 3a, for producing the microstructural element 10, e.g. an MEMS component, a reinforced anchorage with improved mechanical stability is realized with the functional layer 30 reinforced in regions. The starting material can, for example, be a substrate, such as e.g. a silicon substrate (step 110). In step 120 (arranging at least one indentation structure), the indentations 22 in the future anchoring regions with the reinforcement structure 40 are produced, for example, by dry-chemical or wet-chemical etching in the substrate material. Subsequently, in step 130, a cover layer is produced, e.g. by thermal oxidation of a silicon oxide layer (buried oxide). The cover layer 50 then also covers the bottom and the side walls of the indentations 22 in the substrate 20. After that, in step 140, the material, e.g. polysilicon, for the functional layer 30 is deposited. The material thickness of the functional layer 30 is designed to be sufficiently large to not only fill the indentations 22, but also to provide the thickness of the movable functional region 30-1 of the functional layer 30 in the region of the indentations 22. Subsequently, in step 150, the material, e.g. polysilicon, of the functional layer 30 is planarized, e.g. by grinding and polishing as well as by CMP (chemical mechanical polishing).

In the production method 100, the produced functional layer 30 thus has (flexible) regions with a first thickness d1, which transition seamlessly into regions with a greater, second thickness d2 of the reinforcement structures 40 formed in the indentations 22.

In step 160, the substrate 20 is removed in regions (vertically) below the movable functional region 30-1 and the movable functional region 30-1 of the functional layer 30 is exposed. According to the embodiment of FIG. 3a, in the production step 160, the functional layer 30 can also be structured in regions in the plane, e.g. by means of a front-side process, in order to obtain the movable functional region 30-1, e.g. as a deflectable beam element. The functional layer 30 can thus be removed in regions for exposing the movable functional region 30-1 (e.g. as a deflectable beam element). The etching-free process in step 160 can thus actually have three sub-processes according to the embodiment of FIG. 3a: (anisotropic) etching of the substrate 20 from the rear side, (anisotropic) etching of the functional layer 30 from the front side and (isotropic or anisotropic) etching of the cover layer 30 in the exposed regions.

In step 160, using semiconductor processing processes, the movable functional region (the movable microstructure) 30-1 of the functional layer 30, e.g. in the form of a flexible plate of the component 10, is then produced in a region of the functional layer 30 with the smaller first thickness d1, whereas the inventive anchoring of the functional layer 30 on the substrate 20 is advantageously produced in regions 30-2 of the functional layer 30 with the greater thickness d2. The inventive anchoring is realized at the positions where the movable functional region (the flexible plate) 30-1 transitions into rigid regions 30-2 of the microstructural element (MEMS device) 10, i.e. on the frame (the anchoring region) 30-2 and in the illustration in FIGS. 2a-b and 3a-b also on the mass element 28.

In the following, an exemplary basic flow chart (flow diagram) of the inventive production method 100 according to a further embodiment is illustrated with reference to FIG. 3b. FIG. 3b describes, by way of example, a further inventive procedure of the method 100 for producing a microstructural element 10, wherein the functional layer 30, which has, for example, a semiconductor material such as silicon or polysilicon, has a reinforcement structure (an anchor) 40 of increased thickness in the anchoring region 30-2 to the substrate 20. Furthermore, the thickness of the movable functional region 30-1 of the functional layer 30 can be varied locally by means of a further reinforcement structure 42 (e.g. as an anchor for a mass element 28). However, it is pointed out that the embodiment described is applicable to producing any MEMS devices or MEMS microstructures.

As is shown by way of example in the flow chart of the inventive production method 100 illustrated with reference to FIG. 3b, steps 110-160 for producing the microstructural element 10 are performed again, wherein, in contrast to the flow chart of the production method 100 illustrated with reference to FIG. 3a, the reinforcement structures 40, 42 are arranged, by means of further indentation structures 23, at such a position in the substrate 20 that the reinforcement structures (anchorages) 40, 42 (obtained in step 160) are arranged completely on the exposed second main surface region 30-B of the movable functional region 30-1 of the functional element 30, in order to realize the inventive anchorages 40, 42 with increased mechanical stability at the positions where the movable functional region (the flexible plate) 30-1 transitions into rigid regions 30-2 of the microstructural element (MEMS device) 10, i.e. on the frame (the anchoring region) 30-2 and in the illustration in FIGS. 2a-b and 3a-b also on the mass element 28.

In this context, it is further pointed out that the procedure for creating the reinforcement structures (anchor regions) 40, 42 illustrated with reference to the embodiment of FIG. 3b is equally applicable to the embodiment of the inventive production method 100 illustrated with reference to FIG. 12, wherein the indentation structures 23 with a plurality of indentation elements 23-1, . . . , 23-n, with n=2, 3, 4, 5, . . . , (N≥2) are provided in the substrate 20 at such positions so as to obtain the resulting reinforcement structures (anchor regions) 40, 42 with a plurality of reinforcement elements 40-1, . . . , 40-n, with n=2, 3, 4, 5, . . . , (N≥2) and 42-1, . . . , 42-n, with n=2, 3, 4, 5, . . . , (N≥2).

As is illustrated in FIG. 3a, a substrate 20 is provided in step 110. The starting material can thus be a semiconductor substrate, such as e.g. a silicon substrate or an SOI (silicon-on-insulator) substrate.

In the method 100, in step 120 of arranging an indentation structure, initially in a first sub-step 122, a first indentation structure 22 with at least one first indentation element 22-#(with #=1 or 2 or 3. . . ) is arranged in the first main surface region 20-A of the substrate 20, and in a second sub-step 124, a second indentation structure 23 with at least one second indentation element 23-#is arranged in the region of or starting from (the bottom region) of the first indentation structure 22 in the substrate 20 or introduced (etched) into the substrate 20. In step 120, the indentation structures 22, 23 (with one or more indentation elements) are produced, for example, by dry etching or wet etching at the positions where the reinforcement structures 40, 42 (which can optionally also have several reinforcement elements—see e.g. also FIG. 12) can then be produced in the subsequent steps.

In step 130, the cover layer 50 is arranged (applied) on the first main surface region 20-A and in the indentation structures 22, 23 of the substrate 20. The cover layer 50 comprises, for example, an insulation material, such as e.g. an oxide material (buried oxide=BOX). In the case of an oxide material, the oxide layer 50 can be obtained, for example, by a thermal oxidation process of the silicon substrate, e.g. as a silicon oxide layer. The cover layer 50 covers not only the entire first main surface 20-A of the substrate 20 with the bottom and the side walls of the indentation structures 22, 23.

In the subsequent step 140, the functional layer (device layer) 30 is applied on the cover layer 50 on the first main surface region 20-A and in the indentation structures 22, 23 of the substrate 20. The functional layer 30 can, for example, be deposited as a polysilicon material (poly-Si material) on the cover layer 50. The material thickness of the functional layer 30 is to be formed sufficiently large to at least fill the indentation(s) 22, 23.

The functional layer 30 can, for example, be applied by depositing, on the front side 20-A of the substrate 20 covered with the cover layer 50, by means of a CVD (chemical vapor deposition) process, the material, e.g. polysilicon, of the functional layer 30, which then later also forms the movable functional region 30-1 of the functional layer 30. The thickness of the functional layer 30 can, for example, be in a range from 2 μm to about 125 μm.

Alternatively, the functional layer 30 can also comprise or consist of a monocrystalline silicon material, corresponding to an SOI (silicon-on-insulator) structure. SOI substrates 20 are produced, for example, by bonding and thinning silicon substrates and are thus also available at thicker functional layers 30.

The thickness of the cover layer (buried oxide) 50 can, in the case of silicon oxide, typically be in a range between 0.5 μm and 2 μm, independently of the type of functional layer 30.

In step 150, the functional layer 30 is planarized up to (the level of) the cover layer 50 on the (upper) first main surface region 20-A of the substrate 20 in order to obtain a planar first main surface region 30-A of the functional layer 30, wherein the functional layer 30 at its opposite, second main surface region 30-B extends along the substrate 20 and also into the first and second indentation structures 22, 23 of the substrate 20 and forms the reinforcement structures (anchor regions) 40, 42 in the second indentation structure 22.

In step 150, the material of the functional layer 30 is planarized, wherein, under certain circumstances, a considerable material thickness (polysilicon thickness) is to be removed. In addition to a CMP (chemical mechanical polishing) process, further grinding and polishing processes may be required or used. The resulting functional layer 30 thus has regions with a smaller first thickness d1, which transition “seamlessly” into regions (reinforcement regions) 40, 42 with a greater, second thickness d2 (or also third thickness d3) in the indentations 23, i.e. the thickness of the functional layer 30 varies locally over the area (surface) of the substrate 20.

In step 160, according to an embodiment, the movable functional region 30-1 of the functional layer 30 can be exposed by removing the substrate 20 in regions. Thus, the substrate 20 can be removed in regions, e.g. vertically, below the movable functional region 30-1, wherein, in the rear side opening of the substrate 20, a continuous recess (through opening) 26 through the substrate 20 is also formed, which extends completely through the substrate 20 and laterally around the movable functional region 30-1 of the functional layer 30. In order to obtain or expose the movable functional region 30-1 as a deflectable beam element, in the production step 160 according to the embodiment of FIG. 3b, for example, no front-side etching process on the functional layer 30 is required.

Furthermore, in step 160, in the rear side opening of the substrate 20, a rigid element 28, such as e.g. a mass element (inertial mass element), can be formed on the movable functional region 30-1 or within the movable functional region 30-1 of the functional layer 30.

According to an embodiment, step 160 of exposing the movable functional region 30-1 of the functional layer 30 can be performed starting from the second main surface region (rear side) 20-B of the substrate 20 by means of an anisotropic etching process in order to obtain the recess 26 or the through opening (rear side opening) 26 through the substrate 20. Such an anisotropic etching process can, for example, comprise a so-called Bosch process or a DRIE (Deep Reactive Ion Etching) process.

As shown exemplarily in FIG. 3b in step 160, the microstructural element 10 can be obtained in which the movable functional region 30-1 of the functional layer 30 is formed as a beam element (cantilever, bending beam or deflectable plate) clamped on one side optionally with a mass element in the movable functional region 30-1.

FIGS. 4a-b show a comparison of a schematic partial cross-sectional view (a) of an anchoring region 31-2 of a conventional MEMS component 11 to a schematic partial cross-sectional view (b) of an exemplary embodiment of the anchoring region 30-2 of the microstructural element 10 produced according to an embodiment. The functional layer 30 and 31 can in this case comprise polysilicon, the cover layer 50 and 51 can comprise silicon oxide (BOX=buried oxide) and the substrate 20 and 21 can comprise or consist of monocrystalline silicon.

As shown exemplarily in FIG. 4a, a conventional MEMS component 11 has a functional layer 31 which has the same thickness d1 both in the movable functional region 31-1 and in the anchoring region 31-2. The oxide layer 51 is arranged between the functional layer 31 and the substrate 21 in the anchoring region 31-2. Due to the etching-free process of the movable functional region 31-1, when the oxide layer 51 is removed, for example, by isotropic etching in an HF gas phase, the oxide layer 51 can be etched back in the region of the anchoring or an undercut 51-1 arises between the silicon substrate 21 and the functional layer 31 starting from the generated rear side opening 27.

FIG. 4b shows an exemplary embodiment of the anchoring region 30-2 of the microstructural element 10 produced with the reinforcement structure 40 according to an embodiment, as described, for example, with reference to FIGS. 1, 2a-b and 3.

As shown in FIG. 4b, in the microstructural element 10, the reinforcement structure 40 is arranged in the anchoring region 30-2 of the functional layer 30 on the substrate 20, wherein the functional layer has a first thickness d1 in the movable functional region without the reinforcement structure and the functional layer 30 with the reinforcement structure 40 has the greater, second thickness d2 in the anchoring region. The cover layer 50 (silicon oxide) is arranged between the reinforcement structure 40 of the functional layer 30 and the substrate 20, wherein here, too, an undercut 50-1 of the cover layer 50 forms due to the etching-free process (step 160) of the movable functional region 30-1 of the functional layer 30 when the oxide layer 50 is removed, for example, by isotropic etching in an HF gas phase.

In the inventive anchoring according to FIG. 4b, the flexible functional region (the flexible plate) 30-1 and the anchoring region 30-2 of the functional layer 30 have different thicknesses. The thickness d2 of the inventive anchoring region 30-2, also referred to as anchor 40, results from the sum of the thickness d1 of the movable functional region 30-1 and the depth d₂₂ of the indentation 22 in the substrate 20 (in step 120). In general, the thickness d2 is smaller than the material thickness d₃₀ for the functional layer 30 to be deposited (in step 140). In the case of polysilicon for the functional layer 30, which is available, for example, in deposition thicknesses up to about 125 μm, the depth d22 accordingly is not to exceed a value of 125 μm. The thickness d1 of the flexible functional region 30-1 of the functional layer 30 is, for example, at least 2 μm.

In the case of (vertical) deflections Δz perpendicular to the (lateral) substrate plane, maximum mechanical stress S_{MAX} occurs at positions where the movable microstructure 30-1 transitions into the rigid part 30-2 of the component 10. In FIGS. 4a-b, these regions of maximum mechanical stress are marked by dashed circles S_{MAX}.

In the anchoring according to the known technology of FIG. 4a, in addition to the substrate material (monocrystalline silicon) 21 and the polysilicon of the flexible plate 31-1, the silicon oxide of the oxide layer 51 is also located in the region of the maximum stress S_{MAX}. The strength of the anchoring is therefore dominated by the poorer mechanical properties of the oxide material (silicon oxide) of the oxide layer 51 when compared to polysilicon and monocrystalline silicon.

In contrast, in the inventive anchoring according to FIG. 4b, the region of the maximum stress S_{MAX} remains completely in the material, e.g. polysilicon, of the functional layer 30 with the reinforcement element 40. With a sufficiently large anchor thickness d2, the cover layer (buried oxide) 50 located under the anchor is exposed to only low mechanical stress so that the strength of the inventive anchoring is determined by the mechanical properties of the material, e.g. polysilicon, of the functional layer 30.

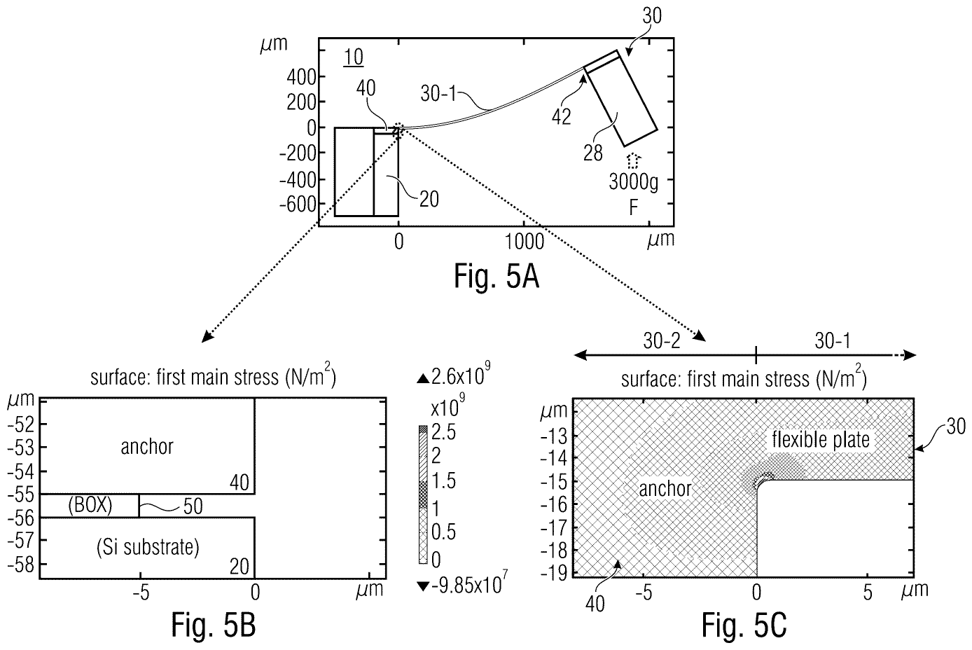

FIGS. 5a-c show an exemplary 2D FEM (finite element method) simulation of the microstructural element (MEMS component) 10 according to FIG. 2a with an anchoring according to FIG. 4b, on the mass element (inertial mass) 28 of which a force acts which corresponds to a shock of 3000 g. For the simulation, the movable microstructure 30-1 comprises a flexible plate composed of polysilicon (functional layer 30) with a length of 1570 μm and a thickness of 15 μm and a mass element 28 with a width of 300 μm which comprises the material of the substrate 20, e.g. monocrystalline silicon. The cover layer 50 composed of silicon oxide (BOX=buried oxide) has a thickness of, for example, 1 μm. Furthermore, an undercut of the cover layer 50 of 5 μm between the flexible plate 30-1 and the substrate 20 was assumed, as can form in the step of exposing 160 (etching-free step), e.g. by isotropic etching of the cover layer 50 in an HF gas phase (HF=hydrofluoric acid). For the simulation, the microstructural element 10 with the inventive anchoring has an anchor thickness d2 of 55 μm, i.e. with a plate thickness d1 of 15 μm, indentations 22 with a depth d22 of 40 μm were provided for this purpose in the substrate 20 (e.g. etched in step 120).

In this context, it is pointed out that the above-mentioned dimensions were chosen purely by way of example for the 2D FEM model in order to illustrate the functionality of the inventive anchoring. In practice, however, the regions indicated on the basis of the description to date can be used for the corresponding dimensions depending on the field of application of the MEMS structural element 10.

FIGS. 5a-c thus show (a) a static simulation of an exemplary FEM model of the microstructural element 10 with the inventive anchoring region, an exemplary representation of the stress distribution (first principal stress in N/m²) (b) below the anchoring region, and (c) at the concave edge in the material (e.g. polysilicon) of the functional layer 30 in the inventive anchoring region.

Thus, FIG. 5a shows the static deflection Δz of the movable microstructure 30-1 under the effect of a force F which corresponds to an acceleration of 3000 g. FIG. 5b shows the mechanical stress in the region of the layer 50 (of the buried oxide=BOX) below the anchoring, as is indicated in FIG. 5a by the lower dashed circle. An undercut of the layer 50 of 5 μm between the flexible plate 30-1 and the substrate 20 is assumed. Such an undercut can form by isotropic etching of the layer 50 (buried oxide) in HF gas phase (e.g. in step 160). The maximum stress in the BOX layer 50 is, for example, about 0.3 GPa. This is below the critical values known for silicon oxide so that (in the present case) a fracture at the anchoring is not to be expected. FIG. 5c represents the distribution of the mechanical stress in the region of the actual anchoring, as is indicated in FIG. 5a by the upper dashed circle. The maximum stress occurs at the concave edge where the flexible plate 30-1 begins.

However, with a value of 2.6 GPa, the maximum stress is relatively high, wherein the inventive anchoring, however, by means of edge rounding (to be explained below), offers an additional possibility of reducing high mechanical stress, in particular high tensile stress, in the material, e.g. polysilicon, of the functional layer 30.

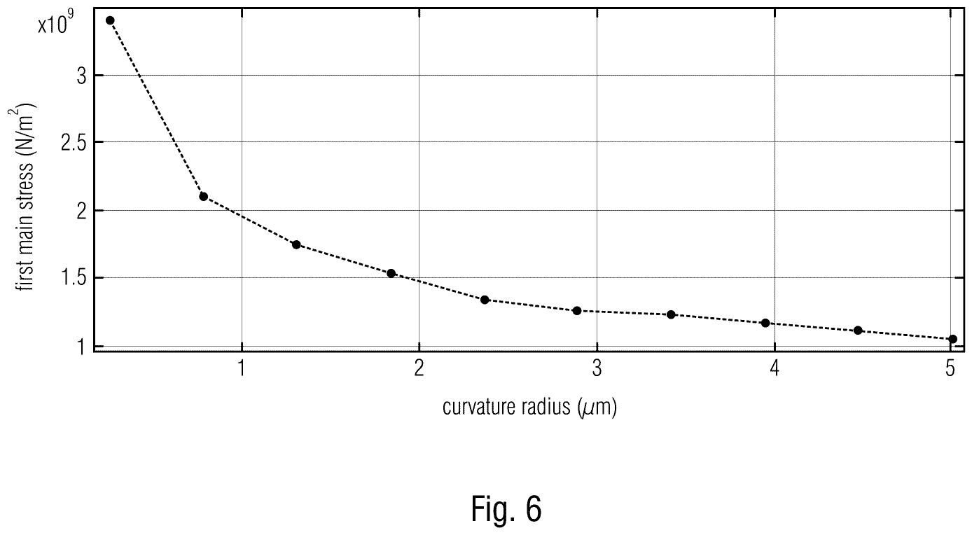

FIG. 6 shows a graphical representation of the profile of the maximum mechanical stress in the anchoring of the FEM model in dependence on the curvature radius of the concave edge in the material (e.g. polysilicon) of the functional layer 30 in the anchoring region 30-2. Thus, FIG. 6 shows the influence of the curvature radius of the concave edge in the polysilicon of the inventive anchoring (see also FIG. 5c) on the maximum mechanical stress at this edge with an anchoring thickness d2 of 55 μm and a thickness d1 of the flexible plate of 15 μm. The calculations took place for the FEM model of FIG. 5a. A force which corresponds to an acceleration of 3000 g acts on the inertial mass 28.

FIG. 6 shows by way of example how the maximum mechanical stress in the inventive anchoring of the FEM model of FIGS. 5a-c with an anchoring thickness of 55 μm changes in dependence on the curvature radius of the concave edge in the material (polysilicon) of the functional layer 30. It is noted that in FIG. 5c a curvature radius of 0.5 μm is assumed, as is to be expected approximately as a result of the thermal oxidation of the substrate 20 for producing the BOX layer 50 (buried oxide) of a thickness of 1 μm. Already from a curvature radius of 1 μm, the maximum mechanical stress (in the transition region between movable functional region 30-1 and reinforcement structure 40 in the anchoring region 30-2) drops to values below 2 GPa.

Consequently, it can be assumed that a movable microstructure 30-1 according to FIG. 5a with a sufficiently high curvature radius at the concave edge of the inventive anchoring withstands a force effect equivalent to an acceleration of 3000 g without suffering damage and thus complies with the JESD22-B110B standard. FIG. 6 further shows that, with an increasing curvature radius, the absolute decrease of the maximum mechanical stress becomes increasingly smaller. In this context, curvature radii between 0.5 μm and 9 μm or between 1 μm and 7 μm or between 1.5 μm and 5 μm are considered to be suitable.

Curvature radii of 1 μm and more can be achieved both at convex and also at concave edges of three-dimensional structures of monocrystalline silicon, for example by annealing in hydrogen at temperatures between 1000° C. and 1150° C. The rounding process also results in smoothing of the first main surface 20-A of the substrate 20 including the surfaces of the at least one indentation. This can lead to an additional reduction of the maximum mechanical stress at the second main surface region of the functional layer 30 and, thus, to a significant increase of the breaking strength of the movable functional region 30-1.

FIG. 7 shows an exemplary basic flow chart of the inventive production method according to a further embodiment.

As illustrated by way of example in FIG. 7, according to a further embodiment, the production method 100, between the production steps 120 and 130 of FIG. 3a-b, can have an (additional) step 125 of performing a rounding process of corner and/or edge regions at the first main surface region 20-A of the substrate 20 provided with the indentation structure 22 (with the at least one indentation 22). By the rounding process, for example, curvature radii between 0.5 μm and 9 μm, between 1 and 7 μm or between 1.5 and 5 μm are obtained at the rounded (curved) concave and/or convex corner and/or edge regions 24 at the first main surface region 20-A of the substrate 20. Furthermore, at the same time, by the rounding process, smoothing of the first main surface region of the substrate provided with the indentation structure and, in particular, of the surfaces of the indentation structure with the at least one indentation can be achieved.

For indentations which are etched, for example, by means of DRIE (or Bosch process), horizontal fluting of the side walls is characteristic, also referred to as scalopping, which is produced by the cyclic alternation between etching and passivation. Scalopping is undesirable since it reduces the mechanical stress of free-standing MEMS structures.

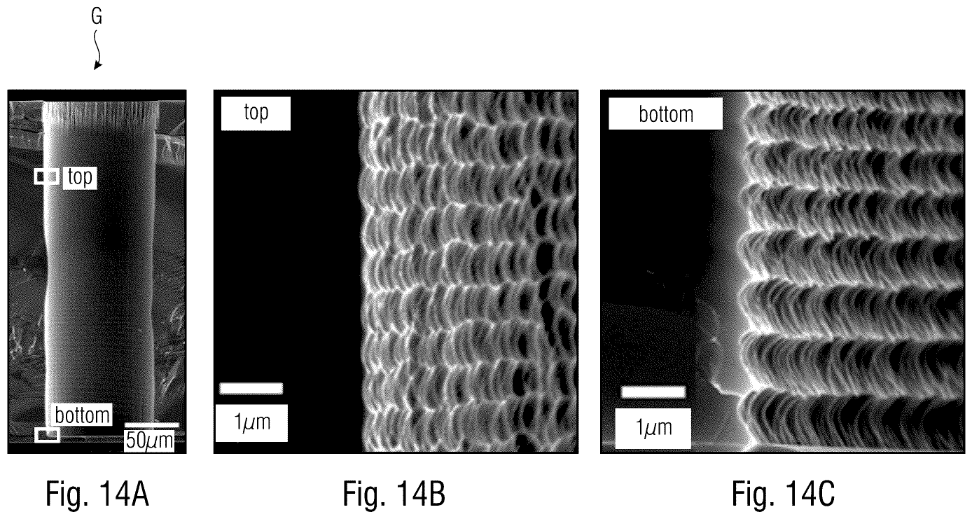

In the following, reference is now made by way of example to FIGS. 14a-c and 15a-c. FIGS. 14a-c show a typical example of the scalopping of the side walls of an indentation with a depth of several 100 μm, produced by means of DRIE (Deep Reactive Ion Etching) in an Si substrate. Frequently, vertical grooves can also be observed, in this example in the upper region of the indentation.

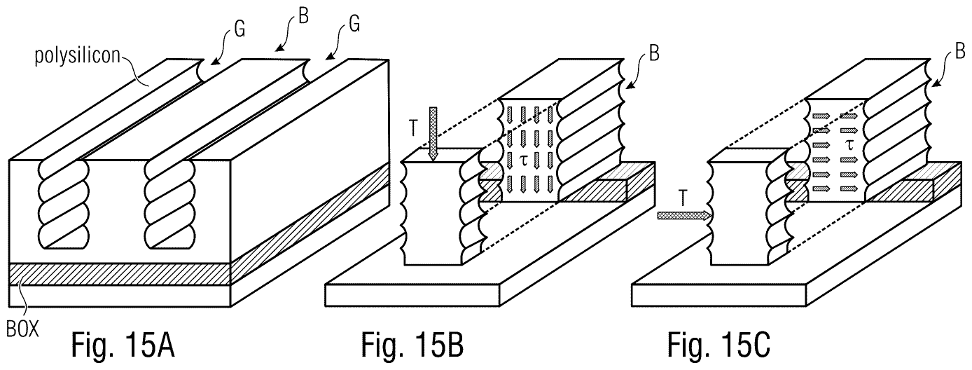

FIGS. 15a-c show an exemplary, schematic representation of the structuring of a polysilicon layer by means of a DRIE process and the resulting surface quality of the side walls of the structure obtained (cantilever). FIG. 15a schematically shows the scalopping for a surface-micromechanical structure made of polysilicon. FIGS. 15b and 15c schematically show a beam “B” made of polysilicon, exposed by etching of the underlying oxide (BOX=buried oxide) and the mechanical stress produced therein under a load T which acts on the free-standing structure from above or from the side. Numerical simulations showed that the breaking strength of such a structure having scalopping can be lower by up to 50% when compared to an identical structure without scalopping.

For example, various procedures can be used to reduce the scalopping. Thus, dry etching (RIE) in SF6 plasma can be used to reduce the scalopping of indentations in monocrystalline silicon. Furthermore, the smoothing of the side walls of indentations produced in monocrystalline silicon can be carried out by means of oxidation and subsequent removal of the oxide layer.

According to an embodiment, the rounding process in step 125 at the first main surface region 20-A of the substrate 20 can also be performed with a dry etching process, an oxidation process or a tempering process in hydrogen, e.g. at temperatures between 1000° C. and 1150° C.

The rounding process for producing curvature radii of 0.5-9 μm, or 1-7 μm or 1.5-5 μm, applied to indentations in the monocrystalline Si substrate, can accordingly also substantially reduce the scalopping or substantially smooth the side walls of the indentations. By rounding edges and corners at as well as smoothing the first main surface region of the substrate provided with the at least one indentation, correspondingly rounded (curved) corners and edges and smooth surfaces can be obtained at the second main surface region of the functional layer and thus at the (then obtained) reinforcement structure. Continuing this, a movable microstructure (e.g. a mirror, a cantilever or also a membrane) can be produced which is bounded on all sides by smoothed surfaces without scalopping and has almost only rounded convex and concave corners and edges. As a result, maximum mechanical stress in the functional layer can be reduced significantly (when compared to a non-rounded and unsmoothed state) and the breaking strength of an MEMS component can be additionally increased beyond the previously considered extent.

In practice, microstructural elements 10, such as e.g. MEMS devices, can be exposed to very high mechanical stress which, however, is not to lead to failure of the movable microstructural element 10 despite a high mechanical stress. Vibration harvesters, inertial sensors or micromirrors can, for example, experience very high accelerations due to vibrations, impacts or fall events. Fluids can exert pressure impacts on the movable structures (the movable functional region 30-1) of microphones or pressure sensors. Other forces which act on parts of the device 10 can also cause critical mechanical stress in the movable microstructure, i.e. the movable functional region 30-1 of the functional layer 30.

Since very high mechanical stress values frequently occur at sharp edges and corners of a microstructural element (MEMS device), a significant reduction of the maximum mechanical stress (load) occurring at the microstructural element 10 is obtained by the rounding process shown in step 125 of the production method 100 with the rounding (curving) of edges and corners 44 of the functional layer 30 and smoothing of the surfaces. By rounding the concave or convex edges 44 at the functional layer 30, in particular in the movable functional region 30-1, and smoothing the surfaces, the strength of the microstructural element 10 can thus be significantly increased and, for example, more than doubled.

As can further be seen from FIG. 7, apart from the rounding process 125, the same process steps 110-160 as in the production method 100 illustrated with reference to FIGS. 1 and 3a-b are carried out in the production method 100 illustrated there so that the description of the process flow is equally applicable here.

The method 100 according to FIG. 7 thus represents how producing rounded edges can be integrated into producing the inventive anchoring according to FIGS. 3a-b. The starting material is e.g. a conventional Si substrate (see step 110). In analogy to FIGS. 3a-b, indentations 22 are produced at first (see step 120). Subsequently, the convex and concave edges of the etched structures are rounded, e.g. by H2 annealing of the Si substrate 20 (see step 125). The further procedure again corresponds to FIGS. 3a-b. After producing the cover layer 50 BOX (see step 130), the material of the functional layer 30, e.g. polysilicon, is deposited (see step 140). Subsequently, the material of the functional layer 30 is planarized, e.g. by grinding and polishing, until the intended thickness of the functional layer 30 is achieved (see step 150). Finally, the movable microstructure 30-1 is produced (see step 160). Thus, the functional layer is structured, the substrate material is etched away from the rear side of the substrate with an etch stop on the cover layer 50 and subsequently (optionally) the cover layer 50 is removed in the etched regions.

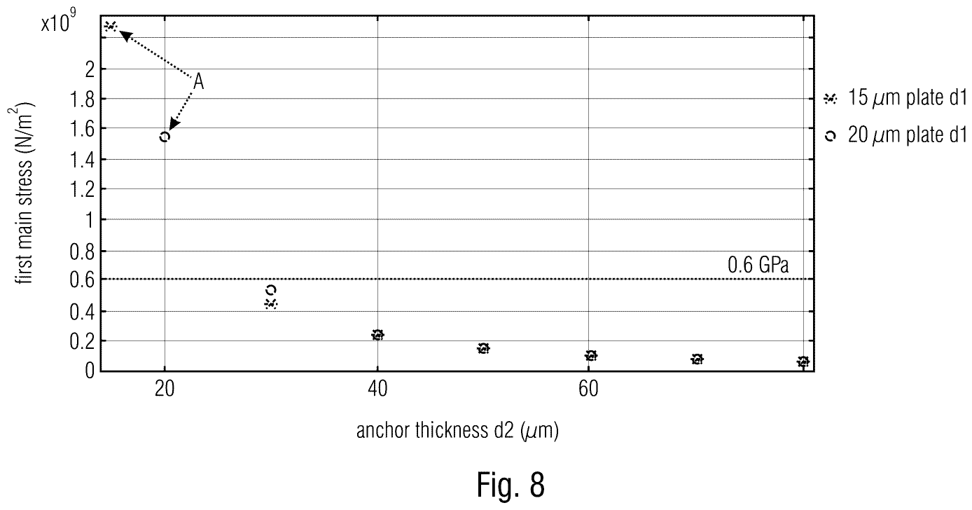

FIG. 8 shows a graphical representation of the maximum mechanical stress in the cover layer (buried oxide=BOX) 50 below the anchoring region 30-2 for two different thicknesses (plate thicknesses) d1 of the movable functional region 30-1 in dependence on the thickness d2 of the anchoring region (e.g. for the FEM model of FIGS. 5a-c). A force which corresponds to an acceleration of 3000 g acts, for example, on the inertial mass. A curvature radius of 2.5 μm was set for the concave edge in the material (e.g. polysilicon) of the functional layer 30, of the actual anchoring (see FIG. 5c).

FIG. 8 illustrates, by way of example, the influence of the (second) thickness d2 of the anchoring and the (first) thickness d1 of the flexible plate 30-1 on the maximum mechanical stress in the cover layer (BOX) 50 below the anchoring (see also FIG. 5b). The FEM model according to FIG. 5a is used for FIG. 8. A force which corresponds to an acceleration of 3000 g acts on the inertial mass. The first two points “A” for each plate thickness d1 with anchoring thicknesses d2 of 15 μm and 20 μm, respectively, still show very high stress values, i.e. far above a value of 0.6 GPa, which can be assumed e.g. as a limit value (lower limit) for the mechanical stress of silicon oxide of the oxide layer 50 for avoiding material fracture. The representation of FIG. 8 thus shows that the thickness d2 of the anchor is to exceed the thickness d1 of the flexible plate for d1 between 15 μm and 20 μm, if possible, by a factor of at least 2 so that the mechanical stress in the BOX 50 remains smaller than 0.6 GPa. Higher factors are of advantage. However, the absolute decrease of the maximum mechanical stress becomes increasingly smaller with an increasing ratio.

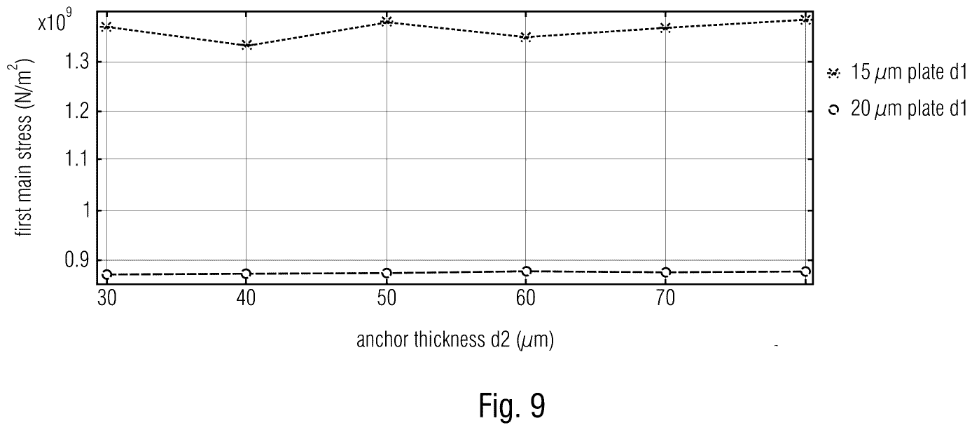

FIG. 9 shows a graphical representation of the maximum mechanical stress at the concave edge in the material (e.g. polysilicon material) of the inventive anchoring region 30-2 for two plate thicknesses d1 of the movable functional region 30-1 in dependence on the thickness d2 of the anchor region 30-2. The calculations are again based on the FEM model of FIG. 5a. A force which corresponds to an acceleration of 3000 g acts on the inertial mass 28. A curvature radius of 2.5 μm is assumed for the concave edge in the material (polysilicon) of the functional layer 30.

As can be seen from FIG. 9, the (second) thickness d2 of the anchor has almost no influence on the maximum mechanical stress at the concave edge in the material (polysilicon) of the functional layer 30 of the inventive anchoring when the edge is rounded (see also FIG. 5c). This is the case in FIG. 9 for plate thicknesses d1 of 15 μm and 20 μm for those anchoring thicknesses d2 for which, according to FIG. 8, the mechanical stress in the BOX 50 remains below the limit of 0.6 GPa. The FEM model of FIG. 5a is again used in the calculations. A force which corresponds to an acceleration of 3000 g acts on the inertial mass 28. It can thus be seen from FIG. 9 that for plate thicknesses d1 between 15 μm and 20 μm, an anchor thickness d2 of 30 μm is already sufficient to withstand shocks of 3000 g.

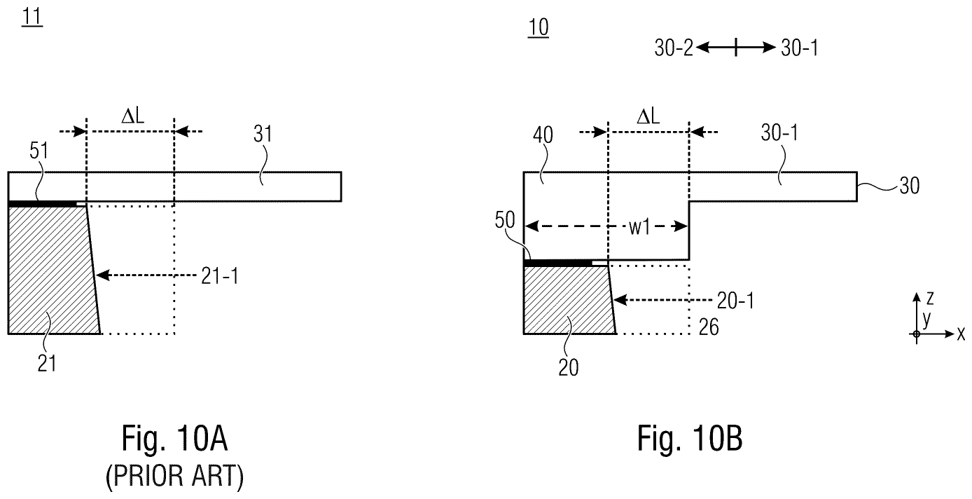

FIGS. 10a-b show a comparison of a schematic partial cross-sectional view (a) of an anchoring region 31-2 of a conventional MEMS component 11 to a schematic partial cross-sectional view (b) of an exemplary embodiment of the microstructural element 10 “produced” with the inventive anchoring region 30-2 according to a further embodiment.

As was described above with reference to the production method 100, according to an embodiment, step 160 of exposing the movable functional region 30-1 of the functional layer 30 can be performed starting from the second main surface region 20-B of the substrate 20 e.g. by means of an anisotropic etching process in order to obtain the rear side opening 26 through the substrate 20. Such an anisotropic etching process can, for example, be a so-called Bosch process or DRIE process.

In such an etching process, the side walls 20-1 of the DRIE etched through opening 26 typically cannot be formed perpendicularly so that a widening of the rear side opening (recess) 26 in the substrate 20 occurs with increasing etching depth, i.e. with an increasing distance from the second main surface region 20-B of the substrate 20. This widening is also referred to as underetching or undercutting, wherein this widening of the rear side opening 26 is indicated in FIG. 10a-b exemplarily with the distance ΔL. Since both the angle of inclination of the side walls and also the undercutting of the etching masking can vary across the substrate, ΔL does not remain constant either. In dependence on the DRIE process and the etching depth, ΔL can definitely be 100 μm and at the same time vary across the substrate (wafer) by several 10 μm.

A corresponding configuration of the reinforcement structure 40 in the anchoring region 30-2 of the functional layer 30 on the substrate 20 can also ensure a mechanically secure anchoring of the movable functional region 30-1 of the functional layer on the substrate 20 when the etching process for producing the rear side opening 26 through the substrate 20 has the (frequently unavoidable) process-technical deviations ΔL.

In the case of an anchoring according to the known technology (see FIG. 10a), ΔL enters directly into the lateral dimensions of the flexible plate 31. In the inventive anchoring (see FIG. 10b), ΔL, in contrast, forms below the anchoring 40 so that the lateral dimensions of the flexible plate 30-1 (with the thickness d1) remain unchanged. Accordingly, the lateral width w1 of the anchors (reinforcement structure) 40 of the inventive anchoring is chosen to be at least greater than the maximum possible value ΔL for the specific production process. The value ΔL here can correspond to the length of the free-standing part of the anchor since the edge of the anchor coincides with the edge of the rear side opening, as shown in FIG. 4b or FIG. 5c. An upper limit for the width of the reinforcement structure 40 does not exist or is predetermined by the design of the device 10.

By the inventive anchoring of the functional layer 30, the influence of process variations on the dimensions of the movable microstructure 30-1 can be reduced when compared to a conventional arrangement.

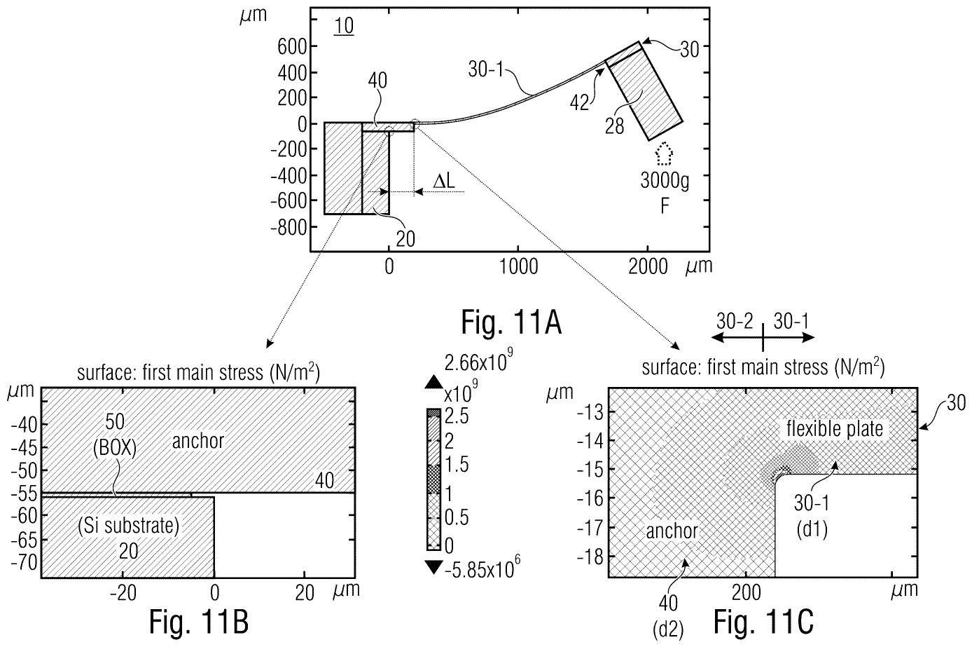

FIGS. 11a-c show (a) a static simulation of an exemplary FEM model of the microstructural element with the inventive anchoring region, (b) an exemplary representation of the stress distribution (first main stress in N/m² below the anchoring region, and (c) at the concave edge in the material (e.g. polysilicon) of the functional layer in the inventive anchoring region (but in contrast to FIGS. 5a-c with an “undercut” ΔL below the inventive anchoring region and a curvature radius (of 0.5 μm) of the concave edge in the transition between the movable functional element 30-1 and the reinforcement structure 40.

FIGS. 11a-c show the influence of a free-standing anchor length or an undercut ΔL of 200 μm on the stress distribution in the oxide layer 50 (buried oxide) below the anchor 40 as well as at the concave edge in the material (polysilicon) of the functional layer 30 for a 2D FEM model equivalent to FIG. 5a-c with an anchoring thickness d2 of 55 μm and a plate thickness d1 of 15 μm. It was assumed here, for example, that the edge of the anchor coincides with the edge of the rear side opening, as shown in FIGS. 4b and 5c.

FIG. 11a shows the deformation of the flexible plate under a static force which corresponds to an acceleration of 3000 g and acts on the inertial mass 28. FIG. 11b illustrates the resulting stress distribution below the anchor 40. An undercut of 5 μm between the flexible plate 30-1 and the substrate 20 is assumed, as can form, for example, by isotropic etching of the BOX 50 (buried oxide) of a thickness of 1 μm in an HF gas phase. FIG. 11c shows the stress distribution at the concave edge 44 in the material (polysilicon) of the functional layer 30. The maximum stress in the material (polysilicon) of the functional layer 30 at 2.66 GPa is only about 2% higher than in the device 10 without undercut, see FIG. 5c. It can thus be assumed that with an anchoring thickness d2 of 55 μm, an undercut ΔL of up to 100 μm as well as a variation of the undercut ΔL of several 10 μm across the wafer 20 have almost no influence on the stress distribution in the inventive anchoring.

FIG. 12 shows an exemplary basic flow chart of the inventive production method 100 according to a further embodiment.

As is shown by way of example in the flow chart of the inventive production method 100 illustrated with reference to FIG. 12, steps 110-160 for producing the microstructural element 10 are performed again, wherein, in contrast to the flow chart of the production method 100 illustrated with reference to FIG. 3a-b, the reinforcement structure 40 is formed with a plurality of reinforcement elements 40-1, . . . , 40-n, with n=2, 3, 4, 5, . . . , (N≥2).

According to the embodiment of the production method 100 of FIG. 12, the reinforcement structure 40 with a plurality of reinforcement elements 40-1, . . . , 40-n can be arranged on the second main surface region 30-B of the functional layer 30. Thus, for example, the reinforcement elements 40-1, . . . , 40-n can be arranged adjacently and/or connected to one another, e.g. in a grid-shaped manner, wherein the reinforcement elements can be arranged to be, e.g., elongated, lamellar, rib-shaped, honeycomb-shaped, grid-shaped, elliptical, circular, wavelike or arcuate, etc., on the second main surface region 30-B of the functional layer 30. The configuration of the reinforcement elements 40-1, . . . , 40-n of the reinforcement structure 40 can depend, for example, on the shape of the movable functional region 30-1, on the anchoring of the movable functional region 30-1 on the substrate 20 and/or on the desired local rigidity of the functional layer 30 or of the movable functional region 30-1 of the functional layer 30.

According to the embodiment of the production method 100 of FIG. 12, the indentation elements 22-1, . . . , 22-n of the indentation structure 22 can be arranged with a maximum width w₂ in the first main surface region 20-A of the substrate 20, wherein the functional layer 30 is applied with a layer thickness which corresponds to at least half the maximum width of the indentation elements 22-1, . . . , 22-n. Thus, the maximum width of the individual indentation elements 22-1, . . . , 22-n can be less than half the thickness of the functional layer 30, wherein the indentation elements 22-1, . . . , 22-n, however, may also have different widths to one another while taking this boundary condition into consideration.

According to the embodiment of the production method 100 of FIG. 12, in step 120, the indentation structure 22 with the indentation elements 22-1, . . . , 22-n can be arranged at such a position in the substrate 20 that the reinforcement structure 40 (then obtained in step 140, 150) with the reinforcement elements 40-1, . . . , 40-n on the second main surface region 30-B of the functional layer 30 is arranged at least partly in an anchoring region of the functional layer on the substrate in order to obtain, e.g., a local modification of the rigidity of the movable functional region 30-1 in the anchoring region. The functional layer 30 in the movable functional region 30-1 without a reinforcement structure has a first thickness d1 and the functional layer 30 with the reinforcement structure 40 in the anchoring region 30-2 has a greater, second thickness d2, with d2>d1.

According to a further embodiment of the production method 100 of FIG. 12, the indentation structure 22 with the indentation elements 22-1, . . . , 22-n (in step 120) can also additionally be arranged at such a position in the substrate 20 that the further reinforcement structure 42 (then obtained in step 140, 150) with the reinforcement elements 42-1, . . . , 42-n is arranged completely on the exposed second main surface region 30-B of the movable functional region 30-1 of the functional element 30 in order to obtain a local modification of the rigidity of the movable functional region 30-1.

The number and arrangement of the indentation elements 22-1, . . . , 22-n in the first main surface region 20-A of the substrate 20 and the resulting number and arrangement of the reinforcement elements 40-1, . . . , 40-n of the reinforcement structure 40 on the second main surface region 30-B of the functional layer 30 can be implemented substantially as desired. The indentations 22 or the reinforcement elements 42 can have an essentially arbitrary profile and can be implemented to be, e.g., elliptical or circular, or wavelike or arcuate, as long as the desired local stiffening of the functional layer 30 is obtained. The indentations 22-1, . . . , 22-n or reinforcement elements 40-1, . . . , 40-n can also overlap in order to form a grid, for example. The repeating distance of the indentations 22 or reinforcement elements 42 can be essentially arbitrary and is not limited to a constant value, as long as the desired local stiffening of the functional layer 30 is obtained.

In the further embodiment of the inventive production method 100 illustrated in FIG. 12, one or more further reinforcement structures 42 can, for example, be arranged (completely) in the movable functional region 30-1 of the functional layer 30. Equally, the reinforcement elements 40-1, . . . , 40-n of the reinforcement structure 40 can also be provided on an anchoring region 30-2 of the functional layer 30 on the substrate 20 and extend (from there) partly into the movable functional region 30-1 of the functional layer 30.

Furthermore, the above-described step 125 of performing a rounding process of corner and/or edge regions 24 at the first main surface region 20-A of the substrate 20 of the production method 100 provided with the at least one indentation 22 is also equally applicable here in order to obtain a rounding of convex and/or concave edges and corners 44 (especially in the movable functional region 30-1) of the functional layer 30 and to obtain particularly smooth surfaces in the second main surface region of the functional layer.

FIG. 12 thus shows a further procedure of the production method 100 in order to realize the inventive anchorage according to a further embodiment. When compared to the procedure according to the production method 100 of FIGS. 3a-b and 7, the costs of producing an inventive anchoring can be reduced with the production method 100 of FIG. 12.

In the following, the method flow of FIG. 12 is once again illustrated and summarized by way of example for silicon process steps, wherein the method 100 is also applicable to other materials, such as metals, semiconductor materials and insulation materials. The starting material is e.g. again an Si substrate 20 (see step 110 of FIG. 12). In contrast to the procedure of FIGS. 3a-b, a number of narrow indentations 22-1, . . . , 22-n is etched into the Si substrate 20 for each anchor 40 instead of an individual indentation 22 (see step 120 of FIG. 12). In contrast to the first variant of the inventive anchoring according to FIGS. 3a-b, the width w2 of the indentations 22-1, . . . , 22-n is to be at least smaller than twice the thickness d30 of the polysilicon layer (functional layer) 30 to be deposited. Subsequently, the buried oxide 50 is produced (see step 130 of FIG. 12), and the polysilicon for the device layer (functional layer) 30 is deposited (see step 140 of FIG. 12). The indentations 22-1, . . . , 22-n are in this case filled and covered by the polysilicon 30. The thickness d30 of the polysilicon layer 30 can correspond approximately or at least to the thickness d1 of the device layer 30. Subsequently, the polysilicon 30 is planarized, e.g. by means of CMP (see step 150 of FIG. 12). Step 160 of FIG. 12 illustrates the subsequent production of the movable microstructure 30-1 using semiconductor process techniques in analogy to the procedures according to FIGS. 3a-b and 7.

According to the embodiment of the inventive production method 100 of FIG. 12, comparatively low production costs can be realized, since the material thickness of the material (polysilicon) of the functional layer 30 to be deposited in step 140 is only slightly thicker than the desired thickness d1 for the movable functional region 30-1 of the functional layer 30. Consequently, the planarization of the material (polysilicon) of the functional layer 30 is also substantially less complex.

The inventive anchoring according to the embodiment of the production method 100 described in FIG. 12 can also be realized with rounding of convex and concave edges in the material (polysilicon) of the functional layer 30, as is described with reference to FIG. 7.

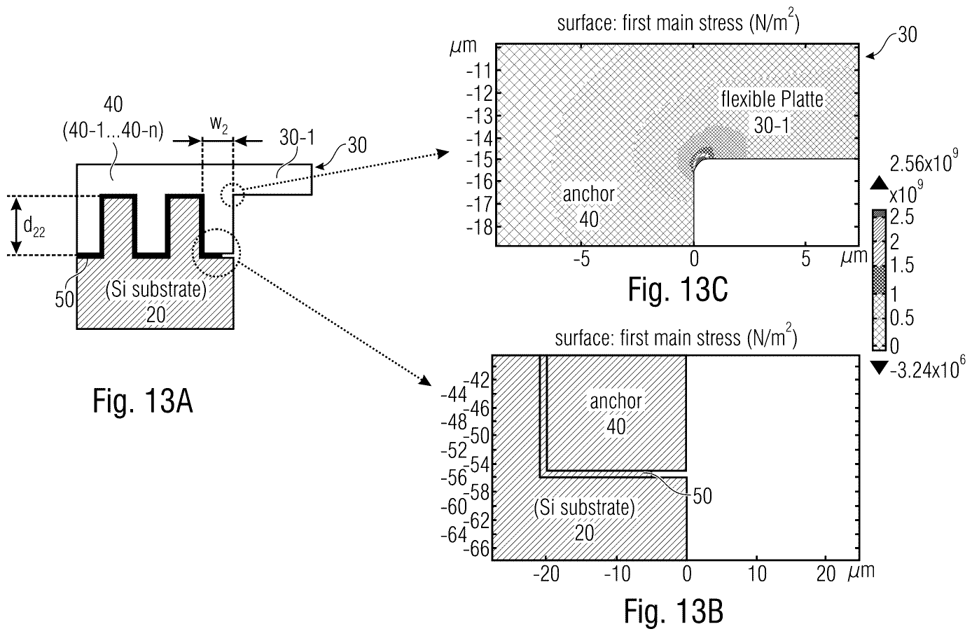

FIGS. 13a-c show (a) schematic and (b) enlarged representations of the inventive anchoring with, for example, a grid-shaped anchoring region 40 as well as (c) the resulting stress distribution below the anchoring region 40 and the stress distribution at a concave edge in the material (e.g. polysilicon) of the functional layer 30. The curvature radius of this edge is 0.5 μm.

FIGS. 13a-c show the distribution of the mechanical stress in an anchoring which was produced according to the embodiment of the production method 100 described in FIG. 12 under the effect of a static force on the inertial mass 28 which corresponds to an acceleration of 3000 g. Apart from the implementation of the anchoring region with the grid-shaped anchoring region 40, the 2D FEM model used here corresponds to the 2D FEM models which were used with reference to FIGS. 5a-c and FIGS. 11a-c.

As can be seen from the schematic 2D representation of FIG. 13a, the anchor 40 is formed by a number of reinforcement elements 40-1, . . . , 40-n in the indentations 22-1, . . . , 22-n with a depth d22 of 40 μm and a width w2 of 20 μm at a repeating distance of 20 μm. FIG. 13b shows the stress distribution below the anchor 40. An undercut of 5 μm between the flexible plate 30-1 and the substrate 20 was assumed, as can form, for example, by isotropic etching of the Buried oxide 50 of a thickness of 1 μm in HF gas phase. FIG. 13c shows the stress distribution at the concave edge in the material (polysilicon) in the transition between the movable functional element 30-1 and the reinforcement structure 40. The maximum stress values in the buried oxide 50 and in the polysilicon 30-1, 40 are still somewhat smaller than in the case of the inventive anchoring according to the procedure according to the invention shown in FIGS. 5a-c.

The number and arrangement of the indentation elements 22-1, . . . , 22-n in the first main surface region 20-A of the substrate 20 and the resulting number and arrangement of the reinforcement elements 40-1, . . . , 40-n of the reinforcement structure 40 on the second main surface region 30-B of the functional layer 30 can be implemented substantially as desired in order to achieve an optimal distribution of the mechanical stress in the inventive anchoring.

The indentations 22 or the reinforcement elements 42 can have an essentially arbitrary profile and can be implemented to be, e.g., elliptical or circular, or wavelike or arcuate, as long as the desired local stiffening of the functional layer 30 is obtained. The indentations 22-1, . . . , 22-n or reinforcement elements 40-1, . . . , 40-n can also overlap in order to form a grid, for example. The repeating distance of the indentations 22 or reinforcement elements 42 can be essentially arbitrary and is not limited to a constant value, as long as the desired local stiffening of the functional layer 30 is obtained. In this case, a widening (undercutting) of the structures to be etched by a value ΔL, as exemplarily shown in FIG. 11a-c , would have no influence on the stability of the inventive anchoring.

The width w2 of the indentations 22-1, . . . , 22-n is to be at least smaller than twice the material thickness d30 of the polysilicon layer (functional layer) 30 to be deposited. The depth d22 of the indentations 22, in contrast, can also be greater than 100 μm or can (theoretically) assume any values. The limit depends on the material of the device layer 30 or the available process for depositing this material.

The inventive anchoring described above with reference to the production method 100 and the microstructural element 10, also in combination with rounding of concave and convex edges and smoothing of the surfaces of the second main surface region of the functional layer, are in principle suitable for all MEMS devices which contain a movable microstructure based on a device layer 30 and require the highest possible strength of the movable microstructure 30-1. The inventive anchoring can be realized anywhere at such positions of an MEMS device where flexible regions 30-1 of the movable microstructure transition into rigid regions 30-2 of the functional layer 30 or where flexible regions 30-1 of the movable microstructure are fixed on a rigid frame 20 of the device 10.

Corresponding volume-micromechanically produced devices would be, for example, vibration harvesters, inertial sensors, loudspeakers, micromirrors, microphones or pressure sensors. Critical mechanical stress occurs here especially in the case of excessive stress of the movable microstructure 30-1, in the case of vibration harvesters, inertial sensors and micromirrors, e.g. due to shocks or in the case of pressure sensors and loudspeakers, e.g. due to overpressure or pressure impacts. Other forces which act on parts of the component can also cause critical mechanical stress in the movable microstructure.

The inventive anchoring described above with reference to the production method 100 and the microstructural element 10 are also applicable in surface-micromechanical devices and in devices in the production of which surface-and volume-micromechanical techniques are combined. In general, the application of an inventive anchoring is not limited to the examples described and MEMS devices mentioned.

In the following, dimensions and materials of the inventive production method 100 and of the microstructural element 10 are once again summarized by way of example for silicon production processes.

In the embodiments described, the device layer 30 can comprise or consist of polysilicon. The thickness d30 of the polysilicon layer deposited for the device layer 30 is to be, for example, more than 2 μm, (advantageously) more than 3 μm or (particularly advantageously) more than 5 μm. In the case of polysilicon, a value for d 30 of 125 μm can be assumed as the (technical) upper limit. In particular, layer thicknesses between 3 μm and 80 μm are (particularly) suitable. The device layer 30 can also comprise or consist of monocrystalline silicon or other materials, such as, for example, metals or dielectrics. The thickness of the material is predetermined by the possibilities of the available deposition processes.

The functional layer 30 can, for example, also be applied at least partly (or completely) as a stack of two or more layers made of the same material or of different materials. Thus, an additional layer for the (resulting) functional layer or the functional layer stack can be applied, for example after planarization (step 150 of the production method 100). Furthermore, individual or all the layers of the functional layer can be planarized or the functional layer stack can finally be planarized in step 150. By configuring the functional layer as a layer stack, the mechanical properties thereof can be set or increased.

Instead of silicon oxide, i.e. the buried oxide, for the cover layer 50, alternative materials can also be used, as long as they are compatible for depositing the device layer 30 or for the production process of the MEMS device 10 and can be removed selectively without the movable microstructure 30-1 or other essential components of the MEMS device 10 being damaged.

A device layer 30 made of metal or a dielectric material can, for example, be combined with a polysilicon layer instead of the buried oxide for the cover layer 50. Polysilicon can be etched isotropically in XeF2 gas phase with high selectivity to many other materials.

The inventive anchoring described above with reference to the production method 100 and the microstructural element 10, also in combination with rounding of concave and/or convex edges and smoothing of the surfaces of the functional layer 30, can provide an improvement in the mechanical strength of a movable, free-standing microstructure 30-1 of the microstructural element (MEMS device) 10, which was produced, for example, using an Si substrate 20 with a device layer 30 made of polysilicon or monocrystalline silicon and a buried oxide 50. Furthermore, for example, production-induced fluctuations in the mechanical properties of the movable microstructure 30-1 of the MEMS device 10 can be reduced.

The embodiments described of the inventive production method 100 and the inventive microstructural element 10 are applicable to all MEMS devices with movable microstructures which can experience mechanical stress during transport, during operation or in extreme situations, which produce high mechanical stress in the anchoring of the movable microstructure 30-1. Examples of corresponding components are vibration harvesters, micromirrors, loudspeakers, microphones, pressure sensors, inertial sensors, resonators, etc.

Although some aspects of the present disclosure have been described as features in the context of an apparatus, it is clear that such a description can also be considered as a description of corresponding method features. Although some aspects have been described as features in the context of a method, it is clear that such a description can also be considered as a description of corresponding features of an apparatus or of the functionality of an apparatus.

In the preceding detailed description, various features have partly been grouped together in examples in order to rationalize the disclosure. This type of disclosure is not to be interpreted as the intention that the claimed examples have more features than are explicitly indicated in each claim. Rather, as the following claims reflect, the subject-matter may be in less than all the features of a single disclosed example. Consequently, the following claims are hereby incorporated into the detailed description, wherein each claim may stand as its own separate example. While each claim may stand as its own separate example, it is to be noted that, although dependent claims in the claims refer back to a specific combination with one or more other claims, other examples also encompass a combination of dependent claims with the subject-matter of any other dependent claim or a combination of any feature with other dependent or independent claims. Such combinations are included unless it is stated that a specific combination is not intended. Furthermore, it is intended that a combination of features of a claim with any other independent claim is also included, even if this claim is not directly dependent on the independent claim.

While this invention has been described in terms of several embodiments, there are alterations, permutations, and equivalents which fall within the scope of this invention. It should also be noted that there are many alternative ways of implementing the methods and compositions of the present invention. It is therefore intended that the following appended claims be interpreted as including all such alterations, permutations and equivalents as fall within the true spirit and scope of the present invention.

### LIST OF REFERENCES

[1] Merz et al., “PSM-X2—Polysilicon surface micromachining process platform for vacuum-packaged sensors”, Proc. MST-Kongress, Freiburg, Germany, 1.012 Oct. 2005

[2] Marenco et al., “Investigation of key technologies for system-in-package integration of inertial MEMS”, Proc DTIP, Rome, Italy, Apr. 1-3, 2009

[3] Vercesi et al., “Thelma-double—A new technology platform for manufacturing of high-performance MEMS inertial sensors”, Proc. MEMS, Tokyo, Japan, Jan. 9-13, 2022

[4] Hong et al., “Fatigue experiments on single crystal silicon in an oxygen-free environment”, J. Microelectromech. Sys., Vol. 24, No. 2, April 2015

[5] Alter et al., “Characterization of accelerated fatigue in thick epi-polysilicon vacuum encapsulated MEMS resonators”, J. Microelectromech. Sys., Vol. 29, No. 6, December 2020

[6] Alter et al., “First fatigue measurements on thick epi-polysilicon MEMS in ultra-clean environment”, Solid-State Sensors, Actuators and Microsystems Workshop, Hilton Head Island, South Carolina, USA, Jun. 3-7, 2018

[7] Hatty et al., “Fracture toughness, fracture strength and stress corrosion cracking of silicon dioxide thin films”, J. Microelectromech. Sys., Vol. 17, No. 4, 2008

[8] Tsuchiya et al., “Tensile testing of insulating thin films; humidity effect on tensile strength of SiO2 films”, Sensors and Actuators 82 (2000)

[9] Fujiyoshi et al., “Improved anchor design for flat MEMS structure by suppressing deformation due to buried-oxide stress on silicon-on-insulator wafer”, J. Micromech. Microeng. 31 (2021) 045001

[10] Renaud et al., “Improved mechanical reliability of MEMS piezoelectric vibration energy harvesters for automotive applications”, Proc. MEMS, San Francisco, CA, USA, Jan. 26-30, 2014

[11] Yokota et al., “Thickness control of cantilever beam for robust and high-power MEMS energy harvester”, Proc. PowerMEMS, Salt Lake City, Utah, USA, Dec. 12-15, 2022

[12] Ngo et al., “Corner rounding to strengthen silicon pressure sensors using DRIE”, Proc. SENSORS, Lecce, Italy, Oct. 26-29, 2008

[13] Mescheder et al., “Corner rounding of sharp silicon punching tool edges by local oxidation of silicon”, Microelectronic Engineering 141 (2015)

[14] Shimizu et al., “Mechanism and control technology of trench corner rounding by hydrogen annealing for highly reliable trench MOSFET”, Proc. International Symposium on Power Semiconductor Devices and IC's, Naples, Italy, Jun. 4-8, 2006

[15] Park et al., “Low-temperature smoothing method of scalloped DRIE trench by post-dry etching process based on SF₆ plasma”, Micro and Nano Syst Lett (2020) 8:14

[16] Bertini et al., “Scalloping and stress concentration in DRIE-manufactured comb drives”, MDPI Actuators 2018, 7, 57

[17] Mohammed et al., “Smoothening of scalloped DRIE trench walls”, Materials Science in Semiconductor Processing 63 (2017) 83-89

1. A method for producing a microstructural element, comprising:
providing a substrate,
arranging an indentation structure in a first main surface region of the substrate,
arranging a cover layer on the first main surface region and in the indentation structure of the substrate,
applying a functional layer on the cover layer on the first main surface region and in the indentation structure of the substrate;
planarizing the functional layer in order to acquire a planar first main surface region of the functional layer, wherein the functional layer at its opposite, second main surface region extends along the substrate and also into the indentation structure of the substrate and forms a reinforcement structure in the indentation structure; and
exposing a movable functional region of the functional layer at least by removing the substrate in regions below the movable functional region, wherein the reinforcement structure is arranged at least partly in an anchoring region of the functional layer on the substrate, and wherein the functional layer without the reinforcement structure comprises a first thickness d1 and the functional layer with the reinforcement structure comprises a greater, second thickness d2, with d2>d1.

2. The method according to claim 1, wherein the indentation structure is arranged in the substrate with such a depth and the functional layer is applied on the substrate with such a thickness that, after planarization, the reinforcement structure of the functional layer in the anchoring region comprises a greater, second thickness d2, with d2≥2*d11.

3. The method according to claim 1, wherein the indentation structure is arranged in the substrate with such a depth and the functional layer is applied on the substrate with such a thickness that, after planarization, the first thickness d1 of the functional layer is between 2 and 125 μm or between 3 and 80 μm and the second thickness d2 of the reinforcement structure, with d2≥2*d1, is between 4 and 250 μm or between 6 and 160 μm.

4. The method according to claim 1, wherein, in the step of exposing a movable functional region of the functional layer, the cover layer is also removed at least in regions (vertically) below the movable functional region.

5. The method according to claim 1, wherein the reinforcement structure is arranged as a one-piece reinforcement element on the second main surface region of the functional layer.

6. The method according to claim 1, wherein the reinforcement structure with a plurality of reinforcement elements is arranged on the second main surface region of the functional layer.

7. The method according to claim 6, wherein the indentation elements of the indentation structure with a plurality of indentation elements are arranged with a maximum indentation width in the first main surface region of the substrate, and wherein the functional layer is applied with a layer thickness which corresponds to at least half the maximum indentation width of the indentation elements.

8. The method according to claim 1, further comprising:
performing a rounding process of edge regions at the first main surface region of the substrate provided with the at least one indentation in order to provide curvature radii between 0.5 μm and 9 μm, between 1 and 7 μm or between 1.5 μm and 5 μm at the edge regions.

9. The method according to claim 8, wherein the rounding process is performed with a dry etching process, wet etching process, oxidation process or tempering process in hydrogen.

10. The method according to claim 1, wherein the step of exposing the movable functional region of the functional layer is performed starting from the second main surface region by means of an anisotropic etching process.

11. The method according to claim 1, wherein the substrate comprises a silicon material, the functional layer comprises a poly-Si material and the cover layer comprises an oxide material.

12. The method according to claim 1, wherein the microstructural element is formed as a deflectable device.

13. The method according to claim 1,
wherein in the step of arranging an indentation structure, a first indentation structure with at least one first indentation is arranged in the first main surface region of the substrate, and a second indentation structure with at least one second indentation is arranged in the region of or starting from the first indentation structure in the substrate,
wherein in the step of arranging a cover layer, the cover layer is arranged on the first main surface region and in the first and second indentation structures of the substrate,
wherein in the step of applying a functional layer, the functional layer is applied on the cover layer on the first main surface region and in the first and second indentation structures of the substrate; and
wherein in the step of planarizing, the functional layer is planarized up to (the level of) the cover layer on the first main surface region of the substrate in order to acquire a planar first main surface region of the functional layer, wherein the functional layer at its opposite, second main surface region extends along the substrate and also into the first and second indentation structures of the substrate and forms the reinforcement structure in the second indentation structure.

14. A microstructural element, comprising:
a substrate provided with a recess, and
a functional layer which spans the recess in the substrate with a movable functional region and comprises a planar first main surface region, wherein a second, opposite main surface region of the functional layer is coupled to the substrate at an edge region, and wherein the functional layer, at its second main surface region, comprises at least one reinforcement structure connected directly to the functional layer or formed integrally therewith,
wherein the at least one reinforcement structure is arranged at least partly in an anchoring region of the functional layer on the substrate, and wherein the functional layer in the movable functional region without a reinforcement structure comprises a first thickness d1 and the functional layer with the reinforcement structure in the anchoring region comprises a greater, second thickness d2, with d2>d1.

15. The microstructural element according to claim 14, wherein the reinforcement structure of the functional layer comprises the greater, second thickness d2, with d2≥2*d1, in the anchoring region.

16. The microstructural element according to claim 14, wherein the reinforcement structure is arranged as a one-piece reinforcement element.

17. The microstructural element according to claim 14, wherein the reinforcement structure comprises a plurality of reinforcement elements which are arranged on the second main surface region of the functional layer.

18. The microstructural element according to claim 14, wherein the first thickness d1 of the functional layer is between 2 and 125 μm or between 3 and 80 μm and the second thickness d2 of the functional layer with the reinforcement structure, with d2≥2*d1, is between 4 and 250 μm or between 6 and 160 μm.

19. The microstructural element according to claim 14, wherein edge regions are rounded at the movable region of the functional layer and comprise curvature radii between 0.5 μm and 9 μm, between 1 and 7 μm or between 1.5 and 5 μm.

20. The microstructural element according to claim 14, wherein the substrate comprises a silicon material, the functional layer comprises a poly-Si material and a cover layer, between the substrate and the functional layer, comprises an oxide material.

21. The microstructural element according to claim 14, wherein the microstructural element is formed as a deflectable device.
